(19) United States
(12) Patent Application Publication
(10) Pub. No.: US 2005/0148198 A1
(43) Pub. Date: Jul. 7, 2005

(54) Texturing a semiconductor material using negative potential dissolution (NPD)

(75) Inventors: Yair Ein-Eli, Haifa (IL); David Starosvetsky, Yokneam IIit (IL); Joseph Yahalom, Haifa (IL)

Correspondence Address: G.E. EHRLICH (1995) LTD.;c/o ANTHONY CASTORINA, SUITE 207, 2001 JEFFERSON DAVIS HIGHWAY, ARLINGTON, VA, 22202, US

(73) Assignee: Technion Research & Development Foundation Ltd.

(21) Appl. No.: 10/750,969

(22) Filed: Jan. 5, 2004

(51) Int. Cl. B23H 3/00; H01L 21/00

(52) U.S. Cl. 438/746

(57) ABSTRACT

Texturing a semiconductor material using negative potential dissolution (NPD), by applying highly negative (cathodic) potentials during conditions of wet etching, and a textured semiconductor material formed therefrom. Semiconductor material is subjected to wet etching conditions, negative biasing at more negative than −60 V, and, specifically controlled and directed illumination by optically processed non-ambient light, resulting in significant increase in values of cathodic current density, and, rate and extent of texturing, of the semiconductor material as a function of time. As cut unpolished semiconductor material is subjected to wet etching conditions and negative biasing, during non-specifically controlled and directed illumination by unprocessed ambient light. Illumination of the as cut unpolished semiconductor material is not needed for increasing values of cathodic current density, and, rate and extent of the texturing, and therefore, upon type of textured as cut unpolished semiconductor material formed therefrom. Particularly applicable to manufacturing solar cells from semiconductor materials.

### FIELD AND BACKGROUND OF THE INVENTION

The present invention relates to methods for texturing semiconductor materials which are based on applying negative (cathodic) potentials during conditions of wet etching, and more particularly, to a method for texturing a semiconductor material using the technique of negative potential dissolution (NPD), and a textured semiconductor material formed therefrom. The present invention is generally applicable to a wide variety of different types of semiconductor materials, including, for example, different types of polished semiconductor materials, and different types of ‘as cut’ unpolished semiconductor materials. The present invention is generally applicable to a variety of different fields and sub-fields requiring or involving texturing the surface of semiconductor materials and textured semiconductor materials formed therefrom, and is particularly applicable to the field of manufacturing solar cells or photovoltaic panels from semiconductor materials, involving texturing surfaces of the semiconductor materials for the objective of decreasing reflectance of incident sunlight away from the semiconductor material surfaces, thereby improving trapping of the solar energy inside the semiconductor materials of the solar cells or photovoltaic panels.

The field of texturing, based on etching, a semiconductor material is relatively well developed, and there is a plethora of prior art teachings of such. Although there exist various different sub-fields and categories of methods and apparatuses for texturing a semiconductor material, currently, the two most widely known, taught about, and applied, sub-fields and categories of methods and apparatuses for texturing a semiconductor material are those based on and involving either wet etching of the semiconductor material or mechanical etching of the semiconductor material, for forming a textured semiconductor material therefrom. An important application of texturing a semiconductor material is for manufacturing a solar cell or photovoltaic panel from the semiconductor material. Texturing is performed for the objective of decreasing reflectance of incident sunlight away from the semiconductor material surface, thereby improving trapping of the solar energy inside the semiconductor material of the solar cell or photovoltaic panel.

Although a wide variety of different types of semiconductor materials may be used for manufacturing solar cells or photovoltaic panels, semiconductor materials entirely made of silicon or at least partly including silicon are the most studied, developed, and commercially used. Texturing silicon for the objective of reducing the reflectivity of the silicon surface is one of the initial steps in manufacturing solar cells or photovoltaic panels, for example, as described by H. Seidel, L. Csepregi, A. Heuberger, and H. Baumgartel, in J. Electrochem. Soc., 137, 3612 (1990), and by J. F. Nijs et al., in “Crystalline Silicon Solar Cells Technology for Today and Tomorrow”, Proc. of the 16^{th} European Photovoltaic Solar Energy Conference, Glasgow, (2000).

Accordingly, the development of a simple, reliable, inexpensive, and environmentally friendly, process of silicon texturing is of significant practical importance to the solar cell industry, for example, as described by H. Seidel et al. (as cited above); J. F. Nijs et al. (as cited above); T. A. Kwa, P. J. French, R. F. Wolffenbuttel, P. M. Sarro, L. Hellemans, and J. Snauwaert, in J. Electrochem. Soc., 142, 1226 (1995); C. R. Tellier and A. Brahim-Bounab, in J. Mater. Sci., 29, 5953 (1994); Q. B. Vu, D. A. Stricker and P. M. Zavracky, in J. Electrochem. Soc., 143, 1372 (1996); K. Sato, M. Shikida, T. Yamashiro, M. Tsunekawa, and S. Ito, in Sensors Actuators, 73, 122 (1999); and, E. Vazsonyi, K. D. Clercq, R. Einhaus, E. V. Kerschaver, K. Said, J. Poortmans, J. Szlufcik, and J. Nijs, in Solar Energy Mat. & Solar Cells, 57, 179, (1999).

Different methods of silicon texturing based on anisotropic or isotropic etching were developed in the last two decades, for example, as described by J. F. Nijs et al. (as cited above); X. G. Zhang, in Electrochemistry of Silicon and its Oxide, Chapter 7, p. 279-349, Kluwer Academic/Plenum Publishers, New York, 2001; M. A. Green, in Advanced in Solar Energy, vol. 8, M. Prince (Ed.), American Solar Energy Society, Boulder, Colo., p. 231, (1993); and M. A. Green, J. Zai, A. Wang, S. R. Wenharn, in IEEE Electron Dev. Lett. EDL-13 317 (1992).

Typically, silicon texturing based on isotropic etching is performed in hydrofluoric acid (HF) containing media, combined with the process of photolithography, for example, as described by X. G. Zhang, S. D. Collins, and R. L. Smith, in J. Electrochem. Soc., 136, 1561, (1989). Such an electrochemical technique involves combining positive (anodic) biasing of the silicon that is exposed to (contacted and wetted by) an aggressive HF etching solution, with illumination of the positively biased exposed silicon surface, and is reasonably effective for increasing control and the rate of the silicon etching/texturing process. However, the use of HF containing media is undesirable because it is accompanied by serious environmental issues relating to its handling and disposal.

Silicon texturing based on anisotropic etching is usually performed in HF-free alkaline solutions, for example, NaOH or KOH solutions, during relatively long term exposure of the silicon surface at open circuit potential (OCP) without electrical biasing. This is because positive (anodic) biasing of silicon in alkaline solutions results in inactivation and/or deactivation of the silicon surface, so that etching, and therefore, texturing, stops. Attempting to increase the rate of etching and texturing of the silicon by using positive (anodic) biasing of the exposed silicon surface results in working in a region within which the treated material (silicon and/or metal) becomes passive or inactivated, or actively dissolves and becomes deactivated, for example, as described by X. G. Zhang et al. (1989, as cited above); P. Allongue, V. Costa-Kieling, H. Gerischer, in J. Electochem. Soc., 140, 1009, (1993); and O. J. Glembocki, R. E. Stahlbush, and M. Tomkieicz, in J. Electochem. Soc. 132, 145-151, (1985). Thus, except when etching/texturing silicon in HF solutions, positive (anodic) biasing is not used.

In the disclosures by Starosvetsky et al., in U.S. Pat. No. 6,521,118; M. Kovler, D. Starosvetsky, Y. Nemirovsky, and J. Yahalom, in Proceedings of The Materials Research Society Symposium, Dec. 1-2, 1998, Boston, Mass., USA, vol. 546, p. 75, (2000); and, D. Starosvetsky, M. Kovler, J. Yahalom, and Y. Ein-Eli, in SOTAPOCS 37 Symposium, Extended Abstract 582, 202^{nd} Fall Meeting of The Electrochemical Society, Salt Lake City, Utah, Oct. 20-24, (2002), the same inventors of the present invention disclosed hereinbelow, introduce and first describe the technique of negative potential dissolution (NPD), based on applying negative (cathodic) potentials, in particular, in the range of between about minus one volt and minus fifty volts relative to a standard reference electrode, such as a standard calomel electrode (SCE), during conditions of wet etching, combined with illumination of the negatively biased exposed silicon surface. Therein is described that the rate of silicon etching/texturing in alkaline media, for example, in NaOH or KOH solutions, could be significantly increased by using negative (cathodic), instead of positive (anodic), biasing of the silicon that is exposed to (contacted and wetted by) the alkaline etching solution, combined with illumination of the negatively biased exposed silicon surface. Moreover, those disclosures also teach about forming a substantially smooth and uniform textured silicon surface by using the negative (cathodic) biasing negative potential dissolution (NPD) technique combined with illumination.

Nevertheless, the above disclosures by the same inventors of the present invention are somewhat limited in the following several respects.

First, therein is teaching of applying the negative potential dissolution (NPD) technique combined with illumination for negative potentials down to only minus fifty volts relative to a standard calomel electrode (SCE). As long as a semiconductor material, such as silicon, remains intact and active, as opposed to becoming inactivated and/or deactivated, during the negative biasing combined with illumination procedure, there is need for investigating and establishing the applicable conditions and controlling operating parameters, and the affects and characteristics, of subjecting a semiconductor material to negative potentials more negative than minus fifty volts. Applicable conditions and controlling operating parameters, and affects and characteristics, of subjecting a semiconductor material to negative potentials down to minus fifty volts are not obviously extendable to subjecting the semiconductor material to negative potentials more negative than minus fifty volts.

Moreover, for example, in the disclosure of U.S. Pat. No. 6,521,118, in particular, as seen in FIG. 2 therein, it was consistently observed that immediately following initiation of illuminating the negatively biased silicon wafer exposed to the NaOH etching solution, the values of cathodic current density, and therefore, rate and extent of texturing of the surface, suddenly and significantly increased, nearly in a step-like manner, but, the values remained essentially constant thereafter as a function of time. Therein, there is no teaching about searching for and establishing conditions and controlling operating parameters which may give rise to increasing values of cathodic current density, and therefore, increasing rate and extent of texturing of the surface, as a function of time during the negative biasing combined with illumination procedure.

Second, therein is teaching of applying the negative potential dissolution (NPD) technique combined with illumination to only polished semiconductor materials, in particular, polished p-type silicon or polished n-type silicon waters. In various fields, particularly in the field of manufacturing solar cells or photovoltaic panels, ‘as cut unpolished’ semiconductor materials are subjected to surface texturing processes for the objective of decreasing reflectance of incident sunlight away from the semiconductor material surfaces. Accordingly, there is need for investigating and establishing the applicable conditions and controlling operating parameters, and affects and characteristics, of subjecting an ‘as cut unpolished’ semiconductor material to the negative potential dissolution (NPD) technique, either combined with illumination or performed without illumination of the negatively biased as cut semiconductor material exposed to the etching solution. Since polishing an ‘as cut unpolished’ semiconductor material tends to significantly change the surface morphology and topology of the original as cut unpolished semiconductor material, applicable conditions and controlling operating parameters, and affects and characteristics, of subjecting a polished semiconductor material to the negative potential dissolution (NPD) technique, are not obviously extendable to subjecting an as cut unpolished semiconductor material to the same negative potential dissolution (NPD) technique.

Third, therein is teaching of forming a substantially smooth and uniform textured silicon surface by using the negative potential dissolution (NPD) technique combined with illumination. Again, with particular reference to manufacturing solar cells from semiconductor materials, there is a need for having a method for texturing an as cut unpolished semiconductor material, such that the textured as cut unpolished semiconductor material formed thereof, is characterized by a selectively rough or patterned surface morphology or topology which decreases reflectance of incident sunlight away from the textured as cut unpolished semiconductor material surface, thereby improving trapping of the solar energy inside the as cut unpolished semiconductor material of the solar cell. Relatedly, again, with particular reference to manufacturing solar cells from semiconductor materials, there is a need for having a method for texturing an as cut unpolished semiconductor material, which is preferentially selective to the different particular orientations in the structure of the as cut unpolished semiconductor material.

There is thus a need for, and it would be highly advantageous to have a method for texturing a semiconductor material using the technique of negative potential dissolution (NPD), based on applying atypically highly negative (cathodic) potentials during conditions of wet etching, and a textured semiconductor material formed therefrom. Moreover, there is a need for such an invention which is generally commercially applicable to a variety of fields and sub-fields requiring or involving texturing the surface of semiconductor materials and textured semiconductor materials formed therefrom. There is a further need for such an invention which is particularly applicable to the field of manufacturing solar cells from semiconductor materials, involving texturing surfaces of the semiconductor materials for the objective of decreasing reflectance of incident sunlight away from the semiconductor material surfaces, thereby improving trapping of the solar energy inside the semiconductor materials of the solar cells or photovoltaic panels.

### SUMMARY OF THE INVENTION

The present invention relates to a method for texturing a semiconductor material using the technique of negative potential dissolution (NPD), based on applying atypically highly negative (cathodic) potentials during conditions of wet etching, and a textured semiconductor material formed therefrom. The rate and extent of texturing of the semiconductor material, and therefore, the type of textured semiconductor material formed therefrom, are controllable and significantly influenced by the several primary operating conditions and parameters of the negative potential dissolution (NPD) technique, such as type of the semiconductor material; type, concentration, temperature, and flow rate, of the etching solution; and, magnitude and duration of the negative biasing; as well as by the type (specifically controlled and directed, or non-specifically controlled and directed), intensity (at least 0.01 watts per cm², or less than 0.01 watts per cm², respectively), wavelength, and duration, of illumination incident upon the negatively biased semiconductor material surface exposed to the etching solution.

The present invention is generally applicable to a wide variety of different types of semiconductor materials, including, for example, different types of polished semiconductor materials, and different types of ‘as cut’ unpolished semiconductor materials. The present invention is generally applicable to a variety of different fields and sub-fields requiring or involving texturing the surface of semiconductor materials and textured semiconductor materials formed therefrom, and is particularly applicable to the field of manufacturing solar cells from semiconductor materials, involving texturing surfaces of the semiconductor materials for the objective of decreasing reflectance of incident sunlight away from the semiconductor material surfaces, thereby improving trapping of the solar energy inside the semiconductor materials of the solar cells or photovoltaic panels. Moreover, the present invention is applicable as (i) a specifically designated, stand-alone, method for texturing a semiconductor material, or (ii) as part of a more encompassing multi-stage method for processing or manufacturing a semiconductor material, or (iii) as part of a more encompassing multi-stage method for processing or manufacturing a product, for example, a solar cell or photovoltaic panel, made from a semiconductor material.

In the first preferred embodiment of the present invention, the negative potential dissolution (NPD) texturing method features subjecting a semiconductor material, for example, a polished semiconductor material, to an etching solution, negative biasing at atypically highly negative (cathodic) potentials more negative than minus sixty volts relative to a standard reference electrode, and specifically controlled and directed illumination by light, preferably, processed non-ambient light, incident upon the negatively biased polished semiconductor material surface contacted and wetted by the etching solution. In this preferred embodiment, the specifically controlled and directed illumination of the negatively biased semiconductor material surface contacted and wetted by the etching solution significantly increases the value of the cathodic current density (A/cm²) of the semiconductor material. This is a direct measure of the increase in the rate and extent of texturing of the semiconductor material, and therefore, of the type of textured semiconductor material formed therefrom. Accordingly, in this preferred embodiment, the negative biasing at atypically highly negative (cathodic) potentials combined with the specifically controlled and directed illumination by light of the semiconductor material surface contacted and wetted by the etching solution, for a period of time, corresponds to a positive synergistic effect on the rate and extent of texturing of the semiconductor material, and therefore, on the type of textured semiconductor material formed therefrom.

In the second preferred embodiment of the present invention, the negative potential dissolution (NPD) texturing method features subjecting an as cut unpolished semiconductor material to an etching solution and negative biasing at atypically highly negative (cathodic) potentials, during non-specifically controlled and directed illumination by light, preferably, unprocessed surrounding or background ambient light, incident upon the negatively biased as cut unpolished semiconductor material. In this preferred embodiment, the non-specifically controlled and directed illumination of the negatively biased as cut unpolished semiconductor material has no measurable affect upon the value of the cathodic current density (A/cm²) of the as cut unpolished semiconductor material, or upon the rate and extent of texturing of the as cut unpolished semiconductor material, and therefore, upon the type of textured as cut unpolished semiconductor material formed therefrom.

Thus, according to the present invention, there is provided a method for texturing a semiconductor material, comprising the steps of: (a) exposing at least part of a surface of the semiconductor material to an etching solution, such that the exposed part of the surface is contacted and wetted by the etching solution; (b) negatively biasing the semiconductor material to a potential more negative than minus sixty volts relative to a standard reference electrode; and (c) illuminating the exposed part of the surface contacted and wetted by the etching solution, during the negative biasing, for a period of time starting from initiation of the illuminating, such that the value of cathodic current density of the semiconductor material is significantly higher at the end of the illumination time period than at the beginning of the illumination time period.

According to another aspect of the present invention, there is provided a method for texturing an as cut unpolished semiconductor material, comprising the steps of: (a) exposing at least part of a surface of the as cut unpolished semiconductor material to an etching solution, such that the exposed part of the surface is contacted and wetted by the etching solution; and (b) negatively biasing the as cut unpolished semiconductor material to a negative potential of at least minus one volt relative to a standard reference electrode for a period of time, during which the as cut unpolished semiconductor material is illuminated by light at an intensity of less than 0.01 watts per cm², such that the value of cathodic current density of the as cut unpolished semiconductor material as a function of time during the time period initially increases to a maximum value, then decreases to a series of values each being significantly less than the maximum value.

According to another aspect of the present invention, there is provided a method for texturing an as cut unpolished semiconductor material, consisting essentially of the steps of: (a) exposing at least part of a surface of the as cut unpolished semiconductor material to an etching solution, such that the exposed part of the surface is contacted and wetted by the etching solution; and (b) negatively biasing the as cut unpolished semiconductor material to a negative potential of at least minus one volt relative to a standard reference electrode for a period of time, such that the value of cathodic current density of the as cut unpolished semiconductor material as a function of time during the time period initially increases to a maximum value, then decreases to a series of values each being significantly less than the maximum value.

According to another aspect of the present invention, there is provided a textured semiconductor material, textured by the method comprising the steps of: (a) providing a semiconductor material; (b) exposing at least part of a surface of the semiconductor material to an etching solution, such that the exposed part of the surface is contacted and wetted by the etching solution; (c) negatively biasing the semiconductor material to a potential more negative than minus sixty volts relative to a standard reference electrode; and (d) illuminating the exposed part of the surface contacted and wetted by the etching solution, during the negative biasing, for a period of time starting from initiation of the illuminating, such that the value of cathodic current density of the semiconductor material is significantly higher at the end of the illumination time period than at the beginning of the illumination time period.

According to another aspect of the present invention, there is provided a textured as cut unpolished semiconductor material, textured by the method comprising the steps of: (a) providing an as cut unpolished semiconductor material; (b) exposing at least part of a surface of the as cut unpolished semiconductor material to an etching solution, such that the exposed part of the surface is contacted and wetted by the etching solution; and (c) negatively biasing the as cut unpolished semiconductor material to a negative potential of at least minus one volt relative to a standard reference electrode for a period of time, during which the as cut unpolished semiconductor material is illuminated by light at an intensity of less than 0.01 watts per cm², such that the value of cathodic current density of the as cut unpolished semiconductor material as a function of time during the time period initially increases to a maximum value, then decreases to a series of values each being significantly less than the maximum value.

According to another aspect of the present invention, there is provided a textured as cut unpolished semiconductor material, textured by the method consisting essentially of the steps of: (a) providing an as cut unpolished semiconductor material; (b) exposing at least part of a surface of the as cut unpolished semiconductor material to an etching solution, such that the exposed part of the surface is contacted and wetted by the etching solution; and (c) negatively biasing the as cut unpolished semiconductor material to a negative potential of at least minus one volt relative to a standard reference electrode for a period of time, such that the value of cathodic current density of the as cut unpolished semiconductor material as a function of time during the time period initially increases to a maximum value, then decreases to a series of values each being significantly less than the maximum value.

### BRIEF DESCRIPTION OF THE DRAWINGS

The present invention is herein described, by way of example only, with reference to the accompanying drawings. With specific reference now to the drawings in detail, it is stressed that the particulars shown are by way of example and for purposes of illustrative description of the preferred embodiments of the present invention only, and are presented in the cause of providing what is believed to be the most useful and readily understood description of the principles and conceptual aspects of the present invention. In this regard, no attempt is made to show structural details of the present invention in more detail than is necessary for a fundamental understanding of the invention, the description taken with the drawings making apparent to those skilled in the art how the several forms of the invention may be embodied in practice. In the drawings:

FIG. 1 is a schematic diagram illustrating an exemplary preferred embodiment of an electrochemical apparatus for implementing the first preferred embodiment and the second preferred embodiment of the negative potential dissolution (NPD) texturing method of the present invention;

FIG. 2 is an empirically determined graphical plot of cathodic current density (A/cm²) measured as a function of time (sec), of an exemplary semiconductor material, polished <100>p-type silicon, during exposure to a potassium hydroxide (KOH) etching solution, 24 wt %, at 20° C., negative biasing at negative (cathodic) potentials of −20 V, −60 V, −80 V, and −100 V, relative to a standard calomel reference electrode (SCE), and specifically controlled and directed illumination by light, in particular, processed non-ambient light, having wavelengths in the range of between 280 nm and 500 nm, and providing an intensity of 2 watts per cm² at the negatively biased silicon surface, in accordance with the first preferred embodiment of the texturing method of the present invention;

FIG. 3 is an empirically determined graphical plot of cathodic current density (A/cm²) measured as a function of applied negative (cathodic) potential (V), at the conditions of the exemplary negative potential dissolution (NPD) with illumination procedure associated with FIG. 2, in accordance with the first preferred embodiment of the texturing method of the present invention;

FIGS. 4(a)-(d) are a sequential series of SEM micrographs of different embodiments of the textured surface of the exemplary <100> p-type silicon semiconductor material, each obtained at a different applied negative (cathodic) potential (V): (a) −40 V, (b) −60 V, (c) −80 V, and (d) −100 V, at the conditions of the exemplary negative potential dissolution (NPD) with illumination procedure associated with FIGS. 1 and 2, in accordance with the first preferred embodiment of the texturing method of the present invention;

FIG. 5 is an empirically determined graphical plot of cathodic current density (A/cm²) measured as a function of time (sec), of an exemplary as cut unpolished semiconductor material, as cut unpolished <100> p-type silicon, during exposure to a potassium hydroxide (KOH) etching solution, 24 wt %, at 20° C., negative biasing at negative (cathodic) potentials of −10 V, −20 V, −40 V, −45 V, and −50 V, relative to a standard calomel reference electrode (SCE), during ‘dark’ conditions of non-specifically controlled and directed illumination by light, in particular, in the form of unprocessed surrounding or background ambient light having an intensity of less than 0.01 watts per cm² incident upon the negatively biased as cut unpolished silicon surface, in accordance with the second preferred embodiment of the texturing method of the present invention;

FIG. 6 is an empirically determined graphical plot of cathodic current density (A/cm²) measured as a function of time (sec), of exemplary as cut unpolished semiconductor materials, as cut unpolished <110> p-type silicon wafer, and as cut unpolished <111> p-type silicon wafer, during separately exposing each to a potassium hydroxide (KOH) etching solution, 24 wt %, at 20° C., negative biasing at a negative (cathodic) potential of −40 V, and −45 V, respectively, relative to a standard calomel reference electrode (SCE), during ‘dark’ conditions of non-specifically controlled and directed illumination by light, in particular, in the form of unprocessed surrounding or background ambient light having an intensity of less than 0.01 watts per cm² incident upon the negatively biased as cut unpolished silicon surface, in accordance with the second preferred embodiment of the texturing method of the present invention;

FIGS. 7(a)-(c) are a series of HRSEM micrographs of exemplary embodiments of the surface of the exemplary as cut unpolished semiconductor materials, as cut unpolished <110> p-type silicon wafer, and as cut unpolished <111> p-type silicon wafer: (a) pristine as cut unpolished <110> p-type silicon without subjection to wet etching and negative biasing; and, (b) textured as cut unpolished <111> p-type silicon and (c) textured as cut unpolished <110> p-type silicon, obtained at the minima values (indicated by the arrows in FIG. 6) of cathodic current density as a function of time, during the exemplary negative potential dissolution (NPD) procedure associated with FIG. 6, in accordance with the second preferred embodiment of the texturing method of the present invention;

FIGS. 8(a)-(f) are a sequential time series of HRSEM micrographs of the surface of the exemplary as cut unpolished <111> p-type silicon wafer during the exemplary negative potential dissolution (NPD) procedure associated with FIG. 6, obtained at the same indicated times during the negative biasing (−45 V) time period: (a) 60 sec, (b) 300 sec, (c) 900 sec, (d) 1800 sec, (e) 2700 sec, and (f) 5100 sec, in accordance with the second preferred embodiment of the texturing method of the present invention; and

FIG. 9 is a graphical plot of cathodic current density (A/cm²) as a function of time (sec), representing an exemplary proposed model graphically illustrating the multi-phenomenological behavior of the value of cathodic current density of an as cut unpolished semiconductor material as a function of time, during the negative biasing time period, during dark conditions, in accordance with the second preferred embodiment of the texturing method of the present invention.

### DESCRIPTION OF THE PREFERRED EMBODIMENTS

The present invention relates to a method for texturing a semiconductor material using the technique of negative potential dissolution (NPD), based on applying atypically highly negative (cathodic) potentials during conditions of wet etching, and a textured semiconductor material formed therefrom. The rate and extent of texturing of the semiconductor material, and therefore, the type of textured semiconductor material formed therefrom, are controllable and significantly influenced by the several primary operating conditions and parameters of the negative potential dissolution (NPD) technique, such as type of the semiconductor material; type, concentration, temperature, and flow rate, of the etching solution; and, magnitude and duration of the negative biasing; as well as by the type (specifically controlled and directed, or non-specifically controlled and directed), intensity (at least 0.01 watts per cm², or less than 0.01 watts per cm², respectively), wavelength, and duration, of illumination incident upon the negatively biased semiconductor material surface exposed to the etching solution.

The present invention is generally applicable to a wide variety of different types of semiconductor materials, including, for example, different types of polished semiconductor materials, and different types of ‘as cut’ unpolished semiconductor materials. The present invention is generally applicable to a variety of different fields and sub-fields requiring or involving texturing the surface of semiconductor materials and textured semiconductor materials formed therefrom, and is particularly applicable to the field of manufacturing solar cells from semiconductor materials, involving texturing surfaces of the semiconductor materials for the objective of decreasing reflectance of incident sunlight away from the semiconductor material surfaces, thereby improving trapping of the solar energy inside the semiconductor materials of the solar cells or photovoltaic panels. Moreover, the present invention is applicable as (i) a specifically designated, stand-alone, method for texturing a semiconductor material, or (ii) as part of a more encompassing multi-stage method for processing or manufacturing a semiconductor material, or (iii) as part of a more encompassing multi-stage method for processing or manufacturing a product, for example, a solar cell or photovoltaic panel, made from a semiconductor material.

In the first preferred embodiment of the present invention, the negative potential dissolution (NPD) texturing method features subjecting a semiconductor material, for example, a polished semiconductor material, to an etching solution, negative biasing at atypically highly negative (cathodic) potentials more negative than minus sixty volts relative to a standard reference electrode, and specifically controlled and directed illumination by light, preferably, processed non-ambient light, incident upon the negatively biased polished semiconductor material surface contacted and wetted by the etching solution. In this preferred embodiment, the specifically controlled and directed illumination of the negatively biased semiconductor material surface contacted and wetted by the etching solution significantly increases the value of the cathodic current density (A/cm²) of the semiconductor material. This is a direct measure of the increase in the rate and extent of texturing of the semiconductor material, and therefore, of the type of textured semiconductor material formed therefrom. Accordingly, in this preferred embodiment, the negative biasing at atypically highly negative (cathodic) potentials combined with the specifically controlled and directed illumination by light of the semiconductor material surface contacted and wetted by the etching solution, for a period of time, corresponds to a positive synergistic effect on the rate and extent of texturing of the semiconductor material, and therefore, on the type of textured semiconductor material formed therefrom.

In the second preferred embodiment of the present invention, the negative potential dissolution (NPD) texturing method features subjecting an as cut unpolished semiconductor material to an etching solution and negative biasing at atypically highly negative (cathodic) potentials, during non-specifically controlled and directed illumination by light, preferably, unprocessed surrounding or background ambient light, incident upon the negatively biased as cut unpolished semiconductor material. In this preferred embodiment, the non-specifically controlled and directed illumination of the negatively biased as cut unpolished semiconductor material has no measurable affect upon the value of the cathodic current density (A/cm²) of the as cut unpolished semiconductor material, or upon the rate and extent of texturing of the as cut unpolished semiconductor material, and therefore, upon the type of textured as cut unpolished semiconductor material formed therefrom.

Herein, for clearly understanding implementation of the present invention, the phrase ‘semiconductor material’, refers to any material exhibiting semiconductor properties, characteristics, and behavior, and, having any geometrical configuration, shape, or form, and, dimensions, and, construction. Additionally, the semiconductor material of the present invention is susceptible to electrochemical etching, in particular, by using the technique of negative potential dissolution (NPD), based on applying atypically highly negative (cathodic) potentials during conditions of wet etching. In a non-limiting manner, several examples of semiconductor materials and selected relevant characteristics thereof, known and taught about in the prior art, which are applicable for implementing the present invention, are provided herein.

For example, the semiconductor material of the present invention is selected from the group consisting of silicon (Si), germanium (Ge), and a combination thereof. Alternatively, the semiconductor material of the present invention is an alloy selected from the group consisting of a silicon-germanium alloy, a silicon-carbon alloy, a germanium-carbon alloy, a silicon-nitrogen alloy, and a combination thereof.

Alternatively, the semiconductor material of the present invention is selected from the group consisting of a metal oxide, a metal phosphide, a metal sulfide, a metal arsenide, a metal selenide, a metal telluride, and a combination thereof. An exemplary metal oxide semiconductor material is selected from the group consisting of zinc oxide (ZnO), cadmium oxide (CdO), and a combination thereof. An exemplary metal phosphide semiconductor material is selected from the group consisting of indium phosphide (InP), zinc phosphide (ZnP), and a combination thereof. An exemplary metal sulfide semiconductor material is selected from the group consisting of copper sulfide (CuS), cadmium sulfide (CdS), and a combination thereof. An exemplary metal arsenide semiconductor material is gallium arsenide (GaAs). An exemplary metal selenide semiconductor material is copper indium selenide (CuInSe). An exemplary metal telluride semiconductor material is selected from the group consisting of calcium telluride (CaTe), cadmium telluride (CdTe), and a combination thereof.

Moreover, any such above stated semiconductor material may also include any type and number of non-semiconductor materials, for example, including inorganic and/or organic non-semiconductor materials.

The doped conductive type of the semiconductor material of the present invention is variable. For example, for silicon, the doped conductive type is selected from the group consisting of a doped p-type silicon, a doped n-type silicon, and a combination thereof.

The grade of the semiconductor material of the present invention is selected from the group consisting of a metallurgical grade and a semiconductor grade. For example, for silicon, there is metallurgical grade silicon (mg-Si) and semiconductor grade silicon.

The geometrical configuration, shape, or form, of the semiconductor material of the present invention is widely variable. For example, the geometrical configuration, shape, or form, of the semiconductor material is selected from the group consisting of amorphous, mono-crystalline, poly-crystalline, multi-crystalline, and a combination thereof. Moreover, for a mono-crystalline, poly-crystalline, multi-crystalline, or combination thereof, type of geometrical configuration, shape, or form, of the semiconductor material of the present invention, the type of crystallinity or crystallographic orientation is variable. For example, for silicon, the type of crystallinity or crystallographic orientation is selected from the group consisting of <100>, <110>, and <111>.

The dimensions of the semiconductor material of the present invention are variable. For example, dimensions of the semiconductor material are selected from the group consisting of on the order of sub-microns, on the order of microns, on the order of millimeters, on the order of centimeters, and a combination thereof. Moreover, implementation of the present invention is scalable to larger, bulk or commercial size, dimensions of the semiconductor material, for example, on the order of at least a meter.

The construction of the semiconductor material of the present invention is widely variable. For example, the construction of the semiconductor material is selected from the group consisting of part of a single assembly, a composite of two or more parts of a single assembly, a single complete assembly, a composite of two or more single complete assemblies, and a combination thereof. For example, the construction of the semiconductor material is selected from the group consisting of part of a single wafer, a composite of two or more parts of a single wafer, a single complete wafer, a composite of two or more single complete wafers, and a combination thereof. For example, the construction of the semiconductor material is selected from the group consisting of a thin film (for example, having a thickness of less than about one hundred microns), a thick film (for example, having a thickness larger than about one hundred microns), and a combination thereof. Moreover, any such above construction of the semiconductor material may also include a substrate. Furthermore, any such above construction of the semiconductor material may also include any type and number of non-semiconductor material constructions.

The semiconductor material of the present invention may be in a non-masked and/or non-patterned form, or, in a masked and/or patterned form.

It is to be fully understood that the semiconductor material used for implementing the negative potential dissolution (NPD) texturing method of the present invention may be any one, or any combination of two or more, of the above described types of semiconductor materials.

For implementing the present invention, any of the above previously listed and described types of semiconductor materials can be provided in a polished form or in an ‘as cut unpolished’ form. Herein, the phrase ‘as cut unpolished semiconductor material’ refers to a cut portion or section of a semiconductor material resulting from subjecting an uncut larger piece of the same semiconductor material to a cutting process, and which is unpolished, that is, having not been subjected to a polishing or similar type of surface smoothing process either before or after the cutting process. Such an as cut unpolished semiconductor material typically features a strongly damaged surface layer (having a thickness of on the order of about ten microns) characterized by any number of various different physicochemical types of surface defects and/or defect zones.

For solar cell and photovoltaic panel manufacturing applications, preferably, the semiconductor material of the present invention has the following aspects: (i) exhibits semiconductor properties, characteristics, and behavior, (ii) has geometrical configuration, shape, or form, and, dimensions, and, construction, (iii) is of a grade, and (iv) is in a polished or in an as cut unpolished form, which are already, or potentially, suitable or applicable for manufacturing a solar cell, a photovoltaic panel, or similar type of component, assembly, or device.

Herein, for properly and clearly understanding implementation of the present invention, in particular, regarding implementation of the first and second preferred embodiments of the method of the present invention, a clear and consistent distinction is made between meaning and usage of the related phrases ‘non-ambient light’, ‘processed non-ambient light’, ‘specifically controlled and directed’, and ‘specifically controlled and directed illumination’, featured in the description of the first preferred embodiment of the method, and, the related phrases ‘ambient light’, ‘unprocessed (surrounding or background) ambient light’, ‘non-specifically controlled and directed’, and ‘non-specifically controlled and directed illumination’, featured in the description of the second preferred embodiment of the method.

Regarding implementation of the first preferred embodiment of the method of the present invention, the phrase ‘non-ambient light’ refers to any light, initially generated by an artificial and/or natural light source, which is intentionally processed, for example, by being filtered, collimated, focused, amplified, and/or attenuated, and directed toward the semiconductor material surface, by manual and/or automatic means. Accordingly, the initially generated non-ambient light becomes ‘processed non-ambient light’. Preferably, the non-ambient light initially generated by the artificial and/or natural light source, together with the non-ambient light formed by the intentional processing, herein, also referred to as processed non-ambient light, are ‘specifically controlled and directed’ for producing light having an intensity of at least 0.01 watts per cm² at a negatively biased semiconductor material surface that is contacted and wetted by an etching solution. By implementing the first preferred embodiment of the method of the present invention, the ‘specifically controlled and directed illumination’ of the negatively biased semiconductor material surface contacted and wetted by the etching solution significantly increases the value of the cathodic current density (A/cm²) of the semiconductor material. This is a direct measure of the increase in the rate and extent of texturing of the semiconductor material, and therefore, of the type of textured semiconductor material formed therefrom.

Preferably, for implementation of the first preferred embodiment of the method, the non-ambient light is initially generated by an artificial light source, for example, a light source element, component, mechanism, or device, which is operatively connected to and powered by a power supply, and which is part of an overall setup or apparatus specifically used for implementing the first preferred embodiment of the method of the present invention. Both, the non-ambient light initially generated by the artificial and/or natural light source, together with the non-ambient light formed by the intentional processing, are specifically controlled and directed, such that there is generating and transmitting light which specifically illuminates at least part of a surface of the semiconductor material that is exposed to the etching solution, while the semiconductor material is subjected to negative biasing. It is to be fully understood that the artificial light source of the non-ambient light is ‘not’, for example, one or more ceiling or table lamps or light fixtures, functioning for generating and transmitting surrounding or background (ambient) light, that illuminate a room or similar enclosure within which the first preferred embodiment of the method of the present invention is implemented.

Regarding implementation of the second preferred embodiment of the method of the present invention, the phrase ‘ambient light’ refers to any surrounding or background light, generated by an artificial and/or natural light source, which is ‘not’ processed (in contrast, as in the first preferred embodiment of the method, for example, by being filtered, collimated, focused, amplified, and/or attenuated, and directed toward the semiconductor material surface) by manual and/or automatic means. Accordingly, the initially generated ambient light remains ‘unprocessed ambient light’. Such unprocessed surrounding or background ambient light is ‘non-specifically controlled and directed’ for producing light having an intensity of less than 0.01 watts per cm² at a negatively biased as cut unpolished semiconductor material surface. By implementing the second preferred embodiment of the method, the ‘non-specifically controlled and directed illumination’ of the negatively biased as cut unpolished semiconductor material has no measurable affect upon the value of the cathodic current density (A/cm²) of the as cut unpolished semiconductor material, or upon the rate and extent of texturing of the as cut unpolished semiconductor material, and therefore, has no measurable affect upon the type of textured as cut unpolished semiconductor material formed therefrom.

Typically, for implementation of the second preferred embodiment of the method, the unprocessed surrounding or background ambient light is generated by an artificial light source, for example, a light source element, component, mechanism, or device, which is operatively connected to and powered by a power supply, and which is ‘not’ necessarily an integral part of an overall setup or apparatus specifically used for implementing the second preferred embodiment of the method of the present invention. The artificial light source of the unprocessed surrounding or background ambient light is ‘not’ specifically controlled and directed, and accordingly, there is continuously generating and transmitting unprocessed surrounding or background ambient light which only generally illuminates the negatively biased as cut unpolished semiconductor material that is exposed to the etching solution. It is to be fully understood that the artificial light source of the unprocessed surrounding or background ambient light is, for example, one or more ceiling or table lamps and/or light fixtures, that exclusively function for continuously generating and transmitting surrounding or background (ambient) light, that illuminate a room or similar enclosure within which the second preferred embodiment of the method of the present invention is implemented. Alternatively, the unprocessed surrounding or background ambient light is generated by a natural light source, for example, natural sunlight generated and transmitted by the sun, that at least partly illuminates a room or similar enclosure within which the second preferred embodiment of the method of the present invention is implemented.

Furthermore, regarding implementation of the second preferred embodiment of the method, in the art of the technique of negative potential dissolution (NPD), based on applying atypically highly negative (cathodic) potentials to a semiconductor material during conditions of wet etching, the non-specifically controlling and directing illumination by light, preferably, unprocessed surrounding or background ambient light, in particular, having an intensity of less than 0.01 watts per cm² incident upon the negatively biased as cut unpolished semiconductor material surface, is referred to as a condition of ‘darkness’ or as a ‘dark’ condition, since by definition, in such an embodiment, the non-specifically controlled and directed illumination of the negatively biased as cut unpolished semiconductor material has no measurable affect upon the value of the cathodic current density (A/cm²) of the as cut unpolished semiconductor material, or upon the rate and extent of texturing of the as cut unpolished semiconductor material, and therefore, has no measurable affect upon the type of textured as cut unpolished semiconductor material formed therefrom. Accordingly, it is as if the second preferred embodiment of the method is implemented in ‘actual darkness’ at ‘dark’ conditions.

As illustratively described in more detail hereinbelow, according to the first preferred embodiment of the present invention, the method for texturing a semiconductor material includes the main steps of: (a) exposing at least part of a surface of the semiconductor material to an etching solution, such that the exposed part of the surface is contacted and wetted by the etching solution; (b) negatively biasing the semiconductor material to a potential more negative than minus sixty volts relative to a standard reference electrode; and (c) illuminating the exposed part of the surface contacted and wetted by the etching solution, during the negative biasing, for a period of time starting from initiation of the illuminating, such that the value of cathodic current density of the semiconductor material is significantly higher at the end of the illumination time period than at the beginning of the illumination time period. Preferably, step (c) of illuminating is performed using processed non-ambient light which is specifically controlled and directed for producing light having an intensity of at least 0.01 watts per cm² at the negatively biased semiconductor material surface contacting the etching solution.

In the first preferred embodiment of the method, the behavior of the value of cathodic current density of the semiconductor material being significantly higher at the end of the illumination time period than at the beginning of the illumination time period, for a given illumination time period of the specifically controlled and directed illumination of the semiconductor material surface contacted and wetted by the etching solution while negatively biased to a potential more negative than minus sixty volts, is a direct measure of the significant increase in the rate and extent of texturing of the surface of the semiconductor material, and therefore, of the type of textured semiconductor material formed therefrom.

The immediately preceding first preferred embodiment of the method of the present invention, for texturing a semiconductor material, is implemented for forming a corresponding textured semiconductor material.

As illustratively described in more detail hereinbelow, according to the second preferred embodiment of the present invention, the method for texturing an as cut unpolished semiconductor material includes the main steps of: (a) exposing at least part of a surface of the as cut unpolished semiconductor material to an etching solution, such that the exposed part of the surface is contacted and wetted by the etching solution; and (b) negatively biasing the as cut unpolished semiconductor material to a negative potential of at least minus one volt relative to a standard reference electrode for a period of time, during which the as cut unpolished semiconductor material is illuminated by light having an intensity of less than 0.01 watts per cm², such that the value of cathodic current density of the as cut unpolished semiconductor material as a function of time during the time period initially increases to a maximum value, then decreases to a series of values each being significantly less than the maximum value. Preferably, step (b) is performed using unprocessed surrounding or background ambient light which is non-specifically controlled and directed for producing light having an intensity of less than 0.01 watts per cm² at the negatively biased semiconductor material surface.

In the second preferred embodiment of the method, the behavior of the value of cathodic current density of as cut unpolished semiconductor material as a function of time, during the negative biasing time period, initially increasing to a maximum value, then decreasing to a series of values each being significantly less than the maximum value, may be considered a direct measure of three different phenomena taking place on the exposed part of the surface contacted and wetted by the etching solution, translating to a direct measure of the rate and extent of texturing of the surface of the as cut unpolished semiconductor material, and therefore, of the type of textured as cut unpolished semiconductor material formed therefrom.

The first phenomenon, associated with the initial increase in the value of cathodic current density of the as cut unpolished semiconductor material to the maximum value, most likely corresponds to the existence of defects and/or defect zones along the exposed part of the surface, since an as cut unpolished semiconductor material typically features a strongly damaged surface layer characterized by any number of various different physicochemical types of surface defects and/or defect zones. Accordingly, during the initial portion of the negative biasing time period, starting from the initiating of the negative biasing of the as cut unpolished semiconductor material, the initial increase in the value of cathodic current density of the as cut unpolished semiconductor material to the maximum value, is a direct measure of the existence of defects and/or defect zones located along the topology or morphology of the exposed part of the surface of the as cut unpolished semiconductor material.

The second and third phenomena, associated with the decrease in the value of cathodic current density of the as cut unpolished semiconductor material to a series of values each being significantly less than the maximum value, most likely correspond to two parallel surface processes simultaneously taking place: (i) removal of defects and/or defect zones located along the topology or morphology of the exposed part of the surface of the as cut unpolished semiconductor material, and (ii) texturing along the topology or morphology of the exposed part of the surface of the as cut unpolished semiconductor material.

The immediately preceding second preferred embodiment of the method of the present invention, for texturing an as cut unpolished semiconductor material, is implemented for forming a corresponding textured as cut unpolished semiconductor material.

Alternatively, according to the second preferred embodiment of the present invention, the method for texturing an as cut unpolished semiconductor material, consists essentially of the steps of: (a) exposing at least part of a surface of the as cut unpolished semiconductor material to an etching solution, such that the exposed part of the surface is contacted and wetted by the etching solution; and (b) negatively biasing the as cut unpolished semiconductor material to a negative potential of at least minus one volt relative to a standard reference electrode for a period of time, such that the value of cathodic current density of the as cut unpolished semiconductor material as a function of time during the time period initially increases to a maximum value, then decreases to a series of values each being significantly less than the maximum value.

The immediately preceding alternative second preferred embodiment of the method of the present invention, for texturing an as cut unpolished semiconductor material, is implemented for forming a corresponding textured as cut unpolished semiconductor material.

In the first preferred embodiment of the present invention, the method for texturing a semiconductor material using the technique of negative potential dissolution (NPD), features the novel and inventive combination of steps of exposing at least part of a surface of the semiconductor material to an etching solution, negatively biasing the semiconductor material to a potential more negative than minus sixty volts relative to a standard reference electrode, and illuminating the exposed part of the surface contacted and wetted by the etching solution, during the negative biasing, for a period of time starting from initiation of the illuminating, such that the value of cathodic current density of the semiconductor material is significantly higher at the end of the illumination time period than at the beginning of the illumination time period.

In the second preferred embodiment of the present invention, the method for texturing an as cut unpolished semiconductor material using the technique of negative potential dissolution (NPD), features the novel and inventive combination of steps of exposing at least part of a surface of the as cut unpolished semiconductor material to an etching solution, and negatively biasing the as cut unpolished semiconductor material to a negative potential of at least minus one volt relative to a standard reference electrode for a period of time, during which the as cut unpolished semiconductor material is either illuminated by light having an intensity of less than 0.01 watts per cm², or is not at all illuminated (‘actual dark’ condition), such that the value of cathodic current density of the as cut unpolished semiconductor material as a function of time during the time period initially increases to a maximum value, then decreases to a series of values each being significantly less than the maximum value.

The method for texturing a semiconductor material using the technique of negative potential dissolution (NPD), based on applying atypically highly negative (cathodic) potentials during conditions of wet etching, and a textured semiconductor material formed therefrom, of the present invention, has several beneficial and advantageous features and characteristics, which are based on, in addition to, or a consequence of, the above described main aspects of novelty and inventiveness.

First, the present invention is generally applicable to a wide variety of different types of semiconductor materials, as previously listed and described above. The semiconductor material may be in a polished form, or in an as cut unpolished form. The semiconductor material may be amorphous, mono-crystalline, poly-crystalline, or multi-crystalline. The semiconductor material may be in a non-masked and/or non-patterned form, or, in a masked and/or patterned form. The dimensions of the semiconductor material are variable, for example, on the order of sub-microns, microns, millimeters, centimeters, and a combination thereof. Implementation of the present invention is scalable to larger, bulk or commercial size, dimensions of the semiconductor material, for example, on the order of at least a meter. This feature is particularly advantageous to applications involving manufacturing a commercial type of solar cell or solar cell type of component, assembly, or device. Moreover, the present invention is generally applicable to a semiconductor material having the following aspects: (i) exhibits semiconductor properties, characteristics, and behavior, (ii) has geometrical configuration, shape, or form, and, dimensions, and, construction, (iii) is of a grade, and (iv) is in a polished or in an as cut unpolished form, which are already, or potentially, suitable or applicable for manufacturing a solar cell, a photovoltaic panel, or similar type of component, assembly, or device.

Second, the present invention is applicable to a variety of different types, concentrations, temperatures, and flow rates, of etching solutions. Etching solutions which may be used for implementing the method of the present invention are, for example, acidic etching solutions, neutral etching solutions, basic or alkaline etching solutions, and molten etching solutions, as further described and exemplified hereinbelow.

Third, the present invention is applicable to a wide range of magnitude of highly negative (cathodic) potentials, as previously described hereinabove, and further illustratively described and exemplified hereinbelow. In particular, regarding the first preferred embodiment of the method, wherein there is negatively biasing the semiconductor material to a potential more negative than minus sixty volts, and preferably, to a potential in a range of between more negative than minus sixty volts and about minus one hundred volts, relative to a standard reference electrode. In particular, regarding the second preferred embodiment of the method, wherein there is negatively biasing the as cut unpolished semiconductor material to a negative potential of at least minus one volt, and preferably, to a negative potential in a range of between at least minus one volt and about minus one hundred volts, relative to a standard reference electrode.

Fifth, the present invention is applicable to different types and ranges of intensity of illumination by light, as previously described hereinabove, and further illustratively described and exemplified hereinbelow. In particular, regarding the first preferred embodiment of the method, wherein there is subjecting the negatively biased semiconductor material surface contacted and wetted by the etching solution to specifically controlled and directed illumination by light, preferably, processed non-ambient light, having an intensity of at least 0.01 watts per cm² at the negatively biased semiconductor material surface. In particular, regarding the second preferred embodiment of the method, wherein there is subjecting the negatively biased as cut unpolished semiconductor material contacted and wetted by the etching solution to non-specifically controlled and directed illumination by light, preferably, unprocessed surrounding or background ambient light, having an intensity of less than 0.01 watts per cm² at the negatively biased semiconductor material surface. In particular, regarding the alternative second preferred embodiment of the method, wherein the negatively biased as cut unpolished semiconductor material contacted and wetted by the etching solution is subjected to no illumination, corresponding to implementation at dark conditions.

Sixth, the present invention, in particular, regarding the first preferred embodiment of the method, is applicable to a wide range of wavelengths of the specifically controlled and directed illumination by processed non-ambient light, as further illustratively described and exemplified hereinbelow. More specifically, wherein the specifically controlled and directed processed non-ambient light has a wavelength in a range of between about 100 nm and about 0.5 mm.

Seventh, the present invention is applicable to a wide range of texturing duration, as illustratively described and exemplified hereinbelow. In particular, regarding the first preferred embodiment of the method, wherein there is subjecting the negatively biased semiconductor material surface contacted and wetted by the etching solution to specifically controlled and directed illumination by light, preferably, processed non-ambient light, for a period of time, for example, of at least about 60 seconds (1 minute), starting from initiation of the illuminating, such that the value of cathodic current density of the semiconductor material is significantly higher at the end of the illumination time period than at the beginning of the illumination time period. In particular, regarding the second preferred embodiment of the method, wherein there is subjecting the negatively biased as cut unpolished semiconductor material contacted and wetted by the etching solution to non-specifically controlled and directed illumination by light, preferably, unprocessed surrounding or background ambient light, for a period of time, for example, of at least about 60 seconds (1 minute), such that the value of cathodic current density of the as cut unpolished semiconductor material as a function of time during the time period initially increases to a maximum value, then decreases to a series of values each being significantly less than the maximum value.

Eighth, the present invention is generally commercially applicable to a variety of fields and sub-fields requiring or involving texturing the surface of semiconductor materials and textured semiconductor materials formed therefrom, and is particularly applicable to the field of manufacturing solar cells from semiconductor materials, involving texturing surfaces of the semiconductor materials for the objective of decreasing reflectance of incident sunlight away from the semiconductor material surfaces, thereby improving trapping of the solar energy inside the semiconductor materials of the solar cells or photovoltaic panels.

Based upon the above indicated aspects of novelty and inventiveness, the present invention significantly widens the scope of presently known techniques and methods for texturing semiconductor materials.

It is to be understood that the present invention is not limited in its application to the details of the order or sequence, and number, of steps and sub-steps of operation or implementation of the method, or to the details of type, composition, construction, arrangement, order, and number, of the components and elements of the device used for implementing the method, set forth in the following description, accompanying drawings, or examples.

For example, for illustratively describing implementation of the present invention, reference is made to an exemplary electrochemical apparatus, wherein are included an electrochemical flow-cell, a flowable etching solution, an electrochemical flow-cell inlet tube, an electrochemical flow-cell outlet tube, an etching solution pump, and an etching solution reservoir, among the main components. During implementation of each of the preferred embodiments of the method of the present invention using such an exemplary electrochemical apparatus, preferably, the etching solution flows at a pre-determined flow rate greater than zero, and is circulated between the etching solution reservoir and the electrochemical flow-cell, via the etching solution pump, the electrochemical flow-cell inlet tube, and the electrochemical flow-cell outlet tube.

It is to be fully understood that each preferred embodiment of the method of the present invention can also be implemented, using the same exemplary electrochemical apparatus, wherein the pre-determined flow rate of the etching solution is zero, that is, wherein the etching solution is essentially stationary (except for Brownian motion) inside the electrochemical flow-cell and along the exposed part of the surface of the semiconductor material, and therefore, is essentially stationary during the texturing of the semiconductor material using the disclosed technique of negative potential dissolution (NPD). The actual flow rate of the etching solution used for implementing the present invention is selected according to the size or scale and throughput (production) of the electrochemical apparatus and of the overall texturing process, and according to the other primary operating conditions and parameters of the negative potential dissolution (NPD) technique, being the type of the semiconductor material; type, concentration, and temperature, of the etching solution; and, magnitude and duration of the negative biasing; as well as of the type (specifically controlled and directed, or non-specifically controlled and directed), intensity (at least 0.01 watts per cm², or less than 0.01 watts per cm², respectively), wavelength, and duration, of illumination incident upon the negatively biased semiconductor material surface exposed to the etching solution.

Accordingly, the present invention is capable of other embodiments or of being practiced or carried out in various ways. Although steps, components, and materials, similar or equivalent to those described herein can be used for practicing or testing the present invention, suitable steps, components, and materials, are described herein.

It is also to be understood that unless otherwise defined, all technical and scientific words, terms, and/or phrases, used herein have either the identical or similar meaning as commonly understood by one of ordinary skill in the art to which this invention belongs. Phraseology, terminology, and, notation, employed herein are for the purpose of description and should not be regarded as limiting.

For example, the second preferred embodiment of the method includes non-specifically controlling and directing illumination by light, preferably, unprocessed surrounding or background ambient light, in particular, having an intensity of less than 0.01 watts per cm² incident upon the negatively biased as cut unpolished semiconductor material, in order to illustrate implementation of the present invention. As previously stated hereinabove, this condition of relatively low level of illumination by light is referred to as a condition of ‘darkness’ or as a ‘dark’ condition, since by definition, in such an embodiment, the non-specifically controlled and directed illumination of the negatively biased as cut unpolished semiconductor material has no measurable affect upon the value of the cathodic current density (A/cm²) of the as cut unpolished semiconductor material, or upon the rate and extent of texturing of the as cut unpolished semiconductor material, and therefore, upon the type of textured as cut unpolished semiconductor material formed therefrom. Accordingly, it is as if the second preferred embodiment of the method is implemented in the ‘dark’.

Additionally, as used herein, the term ‘about’ refers to ±10% of the associated value.

Steps, sub-steps, components, elements, operation, and implementation of a method for texturing a semiconductor material using the technique of negative potential dissolution (NPD), based on applying atypically highly negative (cathodic) potentials during conditions of wet etching, and a textured semiconductor material formed therefrom, according to the present invention, are better understood with reference to the following description and accompanying drawings. Throughout the following description and accompanying drawings, same reference numbers refer to same components or same elements.

In the following illustrative description of the method of the present invention, included are main or principal steps and sub-steps, and main or principal devices, mechanisms, components, and elements, needed for sufficiently understanding proper ‘enabling’ utilization and implementation of the disclosed method. Accordingly, description of various possible required and/or optional preliminary, intermediate, minor, steps, sub-steps, devices, mechanisms, components, and/or elements, which are readily known by one of ordinary skill in the art, and/or which are available in the prior art and technical literature relating to texturing of semiconductor materials, wet etching of semiconductor materials, negative (cathodic) biasing of semiconductor materials, illumination, and manufacturing solar cells from semiconductor materials, are at most only briefly indicated herein.

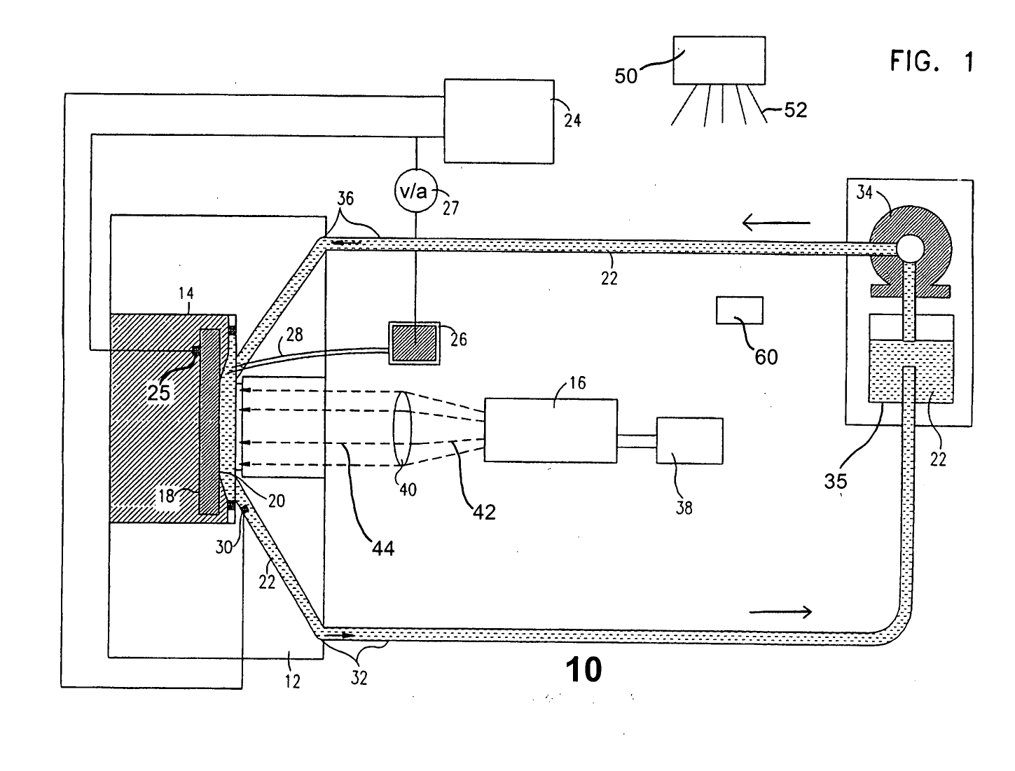

As previously stated hereinabove, the present invention is applicable as (i) a specifically designated, stand-alone, method for texturing a semiconductor material, or (ii) as part of a more encompassing multi-stage method for processing or manufacturing a semiconductor material, or (iii) as part of a more encompassing multi-stage method for processing or manufacturing a product, for example, a solar cell, made from a semiconductor material. Moreover, any of a wide variety of different devices, apparatuses, or systems, may be used for implementing each of the first preferred embodiment, the second preferred embodiment and an alternative thereof, of the method of the present invention. For example, in a non-limiting manner, for implementing the method of the present invention, there is using a slightly modified version of the exemplary electrochemical apparatus described and illustrated in FIG. 1 in the same inventors' U.S. Pat. No. 6,521,118.

Accordingly, reference is now made to FIG. 1 of the present invention, which is a schematic diagram illustrating an exemplary preferred embodiment of an electrochemical apparatus for implementing the method of the present invention, for texturing a semiconductor material, herein, referred to as semiconductor material 18, using the technique of negative potential dissolution (NPD). In FIG. 1, the electrochemical apparatus, herein, referred to as electrochemical apparatus 10, includes the main components: an electrochemical flow-cell 12, a sample holder 14, a flowable etching solution 22, an electrochemical flow-cell inlet tube 36, an electrochemical flow-cell outlet tube 32, an etching solution pump 34, an etching solution reservoir 35, a negative biasing power supply 24, a primary electrode 25, a standard reference electrode 26, a dual function voltmeter (potentiometer)-ammeter 27, a capillary tube 28, a counter-electrode 30, and a timer 60.

In electrochemical apparatus 10, those components, in particular, electrochemical flow-cell 12, sample holder 14, electrochemical flow-cell inlet tube 36, electrochemical flow-cell outlet tube 32, etching solution pump 34, etching solution reservoir 35, standard reference electrode 26, capillary tube 28, and counter-electrode 30, which are at least partly exposed to etching solution 22, and therefore, which are potentially undesirably affected by the material etching or corrosive types of physicochemical properties and characteristics of etching solution 22, are made of appropriate types of glass, plastic (for example, polytetrafluoroethylene (Teflon®), polyetheretherketone), metal (for example, high grade stainless steel, platinum), and/or composite materials thereof, which are sufficiently inert to the etching or corrosive effects of etching solution 22, for at least the duration of the texturing process.

Electrical contact between semiconductor material 18 and the rest of electrochemical flow-cell 12 may be improved by applying an appropriate conducting material, for example, an indium-gallium (In—Ga) amalgam, to the region of contact between semiconductor material 18 and sample holder 14. Such improved electrical contact reduces internal resistance that may exist at the points of electrical contact, translating to the negative (cathodic) bias ‘felt’ by semiconductor material 18 being as close as possible to the negative (cathodic) bias ‘supplied’ by negative biasing power supply 24.

Negative biasing power supply 24 is for controllably, negatively biasing semiconductor material 18, via primary electrode 25, to a highly negative (cathodic) potential of a pre-determined magnitude, relative to standard reference electrode 26. The pre-determined magnitude of the negative potential, and range thereof, are selected according to implementation of the first or second preferred embodiment of the method of the present invention. Preferably, negative biasing power supply 24 is a power supply which is operational in a constant (negative) potential mode, for example, an HP 762 power supply, or an HP 6035A power supply.

The negative potential applied by negative biasing power supply 24, via primary electrode 25, to semiconductor material 18, relative to standard reference electrode 26, is measured and monitored by using the voltmeter function of voltmeter (potentiometer)-ammeter 27, which is operatively connected between negative biasing power supply 24 and standard reference electrode 26. Primary electrode 25, made of an electrically conductive material, for example, stainless steel, is in electrical contact with semiconductor material 18. Standard reference electrode 26 is in electrical contact with electrochemical flow-cell 12 via capillary tube 28. An exemplary standard reference electrode 26 is a saturated calomel reference electrode (SCE). An exemplary capillary tube 28 is a Luggin capillary tube. Counter-electrode 30 is positioned inside electrochemical flow-cell outlet tube 32 and connected to negative biasing power supply 24. Preferably, counter-electrode 30 is made of a material, for example, platinum wire, which is electrically conductive and inert to the etching or corrosive effects of etching solution 22.

For implementing the first preferred embodiment of the method of the present invention, electrochemical apparatus 10 further includes the additional main components: a specifically controlled and directed light source 16, a light source power supply 38, optics 40, specifically controlled and directed-generated light 42, and specifically controlled and directed-processed light 44. For implementing the second preferred embodiment of the method of the present invention, instead of including (that is, without the presence of) specifically controlled and directed light source 16, light source power supply 38, optics 40, specifically controlled and directed-generated light 42, and, specifically controlled and directed-processed light 44, (which components are included in exemplary electrochemical apparatus 10 used for implementing the first preferred embodiment of the method of the present invention), the electrochemical apparatus 10 further includes a non-specifically controlled and directed light source 50, and, a non-specifically controlled and directed-generated (unprocessed) light 52.

The value of intensity of the light incident upon the active or working area of surface 20 of semiconductor material 18, via specifically controlled and directed-processed light 44, in accordance with the first preferred embodiment of the method, or via non-specifically controlled and directed-generated (unprocessed) light 52, in accordance with the second preferred embodiment of the method, corresponds to the value of the intensity of that particular transmitted form of light as measured at a point in the air located at the same position of the active or working area of surface 20 of semiconductor material 18 mounted and held on sample holder 14 in electrochemical apparatus 10. Values of light intensity, herein, expressed in terms of watts per cm² at negatively biased semiconductor material surface 20, are measured and monitored by using any standard type of light intensity measuring device known in the art.

Timer 60 is used throughout for implementing the present invention, for timing the various durations of subjecting semiconductor material 18 to conditions of wet etching, negative biasing, illumination by light, and combinations thereof, during each of the first and second preferred embodiments of the method.

Values of cathodic current density, herein, expressed in units of amps per square centimeter (A/cm²) flowing along the surface of semiconductor material 20, are measured and monitored, via primary electrode 25, by using the ammeter function of voltmeter (potentiometer)-ammeter 27.

Immediately following there is provided a more detailed illustrative description of the first preferred embodiment of the method of the present invention, for texturing a semiconductor material, using the technique of negative potential dissolution (NPD), and a textured semiconductor material formed therefrom. Thereafter, is provided a more detailed illustrative description of the second preferred embodiment of the method of the present invention, and an alternative thereof, for texturing an as cut unpolished semiconductor material, using the technique of negative potential dissolution (NPD), and a textured as cut unpolished semiconductor material formed therefrom. Following thereafter, are specific examples of implementing each of the first and second preferred embodiments of the method of the present invention, respectively.

In Step (a) of the first preferred embodiment of the method of the present invention, for texturing a semiconductor material, there is exposing at least part of a surface of the semiconductor material to an etching solution, such that the exposed part of the surface is contacted and wetted by the etching solution.

Accordingly, with reference to exemplary electrochemical apparatus 10 schematically illustrated in FIG. 1, there is exposing at least part of a surface 20 of semiconductor material 18 to etching solution 22, such that the exposed part of surface 20 is contacted and wetted by etching solution 22.

In exemplary electrochemical apparatus 10, sample holder 14 is for mounting and holding semiconductor material 18 being subjected to the texturing method, at least partly inside of electrochemical flow-cell 12. Semiconductor material 18 has an active or working area of, for example, about 1 cm², and, is mounted and held on sample holder 14 in a configuration for enabling exposure of at least part of the active or working area of surface 20 of semiconductor material 18 to etching solution 22, such that the exposed part of surface 20 is contacted and wetted by etching solution 22.

If semiconductor material 18 has been masked and/or patterned prior to being mounted onto and held by sample holder 14, only those portions of the active or working area of surface 20 of semiconductor material 18 which have not been masked and/or patterned are exposed to, and therefore, contacted and wetted by, etching solution 22. In such cases, ordinarily, the masking and/or patterning material, for example, Si₃N₄, or SiO₂, used for masking and/or patterning semiconductor material 18 is either significantly less susceptible to etching solution 22 than is semiconductor material 18, or is inert to etching solution 22. Moreover, it is noted that, sample holder 14 which is for mounting and holding semiconductor material 18 during implementation of the texturing method of the present invention, may be of such a configuration so as to function as a mask.

Etching solution pump 34 pumps etching solution 22 from etching solution reservoir 35 into and through electrochemical flow-cell 12, via electrochemical flow-cell inlet tube 36, and, pumps etching solution 22 out of electrochemical flow-cell 12 and back into etching solution reservoir 35, via electrochemical flow-cell outlet tube 32. Accordingly, etching solution 22 flows and is circulated between etching solution reservoir 35 and electrochemical flow-cell 12. Electrochemical flow-cell 12 has a volumetric capacity of, for example, about one and a half liters, and etching solution reservoir 35 has a volumetric capacity of, for example, about three liters. Preferably, etching solution pump 34 is a flow controllable peristaltic type of pump.

In general, the type of etching solution 22 is selected from the group consisting of an acidic etching solution, a neutral etching solution, a basic or alkaline etching solution, and a molten etching solution.

An exemplary acidic etching solution is an acidic aqueous solution selected from the group consisting of hydrofluoric acid (HF), nitric acid (HNO₃), phosphoric acid (H₃PO₄), and a combination thereof.

An exemplary neutral etching solution is selected from the group consisting of a neutral aqueous solution including dissolved ions, and, an organic solution. An exemplary neutral aqueous solution including dissolved ions is selected from the group consisting of a neutral aqueous solution of an alkali halogenide, a neutral aqueous solution of an alkaline earth metal halogenide, a neutral aqueous solution of a sulfate, a neutral aqueous solution of an organic salt, and a combination thereof. For a neutral aqueous solution including an alkali halogenide, an exemplary alkali halogenide is selected from the group consisting of lithium chloride (LiCl), sodium chloride (NaCl), and potassium chloride (KCl). For a neutral aqueous solution including an alkaline earth metal halogenide, an exemplary alkaline earth metal halogenide is selected from the group consisting of calcium chloride (CaCl₂) and magnesium chloride (MgCl₂). An exemplary organic solution is selected from the group consisting of ethylene diamine-pirocathecol (EDP), a solution of isopropyl alcohol (IPA) and potassium hydroxide (KOH), and a combination thereof.

An exemplary basic or alkaline etching solution is a basic or alkaline aqueous solution. An exemplary basic or alkaline aqueous solution is an aqueous solution of an alkali hydroxide. An exemplary alkali hydroxide is selected from the group consisting of sodium hydroxide (NaOH), potassium hydroxide (KOH), and a combination thereof.

An exemplary molten etching solution is a solution of a melted salt.

In general, the concentration of the solute in etching solution 22 is at least about 0.001 M. Preferably, the concentration of the solute in etching solution 22 is in a range of between about 8% (wt. solute/wt. solution) and about 50% (wt. solute/wt. solution).

Temperature of etching solution 22 contacting and wetting surface 20 of semiconductor material 18, while flowing and circulating between etching solution reservoir 35 and electrochemical flow-cell 12, is left at room temperature in a range of between about 20° C. and about 25° C., or is controllably increased, via an etching solution heating mechanism (not shown in FIG. 1), to a temperature in a range of between about room temperature and about the boiling point of etching solution 22, or is controllably decreased, via an etching solution cooling mechanism (not shown in FIG. 1), to a temperature in a range of between about room temperature and about the freezing point of etching solution 22. A first example of a controllable etching solution heating/cooling mechanism is an electrically insulated heating/cooling element positioned inside of, and in thermal contact with, etching solution 22, at a location at or between etching solution reservoir 35 and electrochemical flow-cell 12. Such an internal type of etching solution heating/cooling mechanism is inert to the etching or corrosive effects of etching solution 22. A second example of a controllable etching solution heating/cooling mechanism is a heating/cooling element positioned outside of, and in thermal contact with, etching solution 22, at a location at or between etching solution reservoir 35 and electrochemical flow-cell 12.

In general, the temperature of etching solution 22 is in a range of between about the freezing point of etching solution 22 and about the boiling point of etching solution 22. For etching solution 22 being an aqueous etching solution, preferably, the temperature of etching solution 22 is in a range of between about 20° C. and about 90° C., and more preferably, in a range of between about 50° C. and about 90° C.

In general, the flow rate of etching solution 22 contacting and wetting surface 20 of semiconductor material 18 is in a range of between about 0 liter per minute and about 10 liters per minute. Preferably, the flow rate of etching solution 22 contacting and wetting surface 20 of semiconductor material 18, while flowing and circulating between etching solution reservoir 35 and electrochemical flow-cell 12 is in a range of between about 1 mL per minute and about 2.5 liters per minute, and more preferably, in a range of between about 1 mL per minute and about 250 mL per minute.

As previously stated above, for illustratively describing implementation of the present invention, reference is made to an exemplary electrochemical apparatus, that is, electrochemical apparatus 10 illustrated in FIG. 1, wherein are included electrochemical flow-cell 12, flowable etching solution 22, electrochemical flow-cell inlet tube 36, electrochemical flow-cell outlet tube 32, etching solution pump 34, and etching solution reservoir 35, among the main components. During implementation of the first preferred embodiment of the method of the present invention using exemplary electrochemical apparatus 10, preferably, etching solution 22 flows at a pre-determined flow rate greater than zero, and is circulated between etching solution reservoir 35 and electrochemical flow-cell 12, via etching solution pump 34, electrochemical flow-cell inlet tube 36, and electrochemical flow-cell outlet tube 32. It is to be fully understood that the first preferred embodiment of the method of the present invention can also be implemented, using the same exemplary electrochemical apparatus 10, wherein the pre-determined flow rate of etching solution 22 is zero, that is, wherein etching solution 22 is essentially stationary (except for Brownian motion) inside electrochemical flow-cell 12 and along the exposed part of surface 20 of semiconductor material 18 and therefore, is essentially stationary during the texturing of semiconductor material 18 using the disclosed technique of negative potential dissolution (NPD).

The actual flow rate of etching solution 22 used for implementing the first preferred embodiment of the method of the present invention is selected according to the size or scale and throughput (production) of electrochemical apparatus 10 and of the overall texturing process, and according to the other primary operating conditions and parameters of the negative potential dissolution (NPD) technique, being the type of semiconductor material 18; type, concentration, and temperature, of etching solution 22; and, magnitude and duration of the negative biasing (next Step (b)) applied to semiconductor material 18.

Preferably, Step (a) is performed for a period of time of at least about one minute, and typically, for a period of time of about five minutes, prior to initiating negative biasing of semiconductor material 18 in accordance with next Step (b), for enabling the exposed part of surface 20 contacted and wetted by etching solution 22 to reach a steady-state value of an open circuit potential (OCP), relative to standard reference electrode 26, as measured and monitored by using the voltmeter function of voltmeter (potentiometer)-ammeter 27.

In Step (b), there is negatively biasing the semiconductor material to a potential more negative than minus sixty volts relative to a standard reference electrode.

Accordingly, with reference to FIG. 1, there is negatively biasing semiconductor material 18, via primary electrode 25, to a potential more negative than minus sixty volts relative to standard reference electrode 26. Preferably, for performing Step (b) of the first preferred embodiment of the method of the present invention, there is negatively biasing semiconductor material 18 to a potential in a range of between more negative than minus sixty volts and about minus one hundred volts relative to standard reference electrode 26. Semiconductor material 18 may be subjected to negative biasing to a potential more negative than minus one hundred volts relative to standard reference electrode 26. The negative potential applied by negative biasing power supply 24, via primary electrode 25, to semiconductor material 18, relative to standard reference electrode 26, is measured and monitored by using voltmeter (potentiometer)-ammeter 27.

Preferably, for performing Step (b), semiconductor material 18 is negatively biased to a potential more negative than minus sixty volts relative to standard reference electrode 26 for a period of time of at least about one minute, prior to initiating illumination of the exposed part of surface 20 contacted and wetted by etching solution 22, during the negative biasing, in accordance with next Step (c). During this time period, semiconductor material 18 reaches a steady-state value of the applied negative potential, relative to standard reference electrode 26. Additionally, during this time period there is establishing a steady-state of the cathodic current density, typically, having a baseline value of about zero A/cm² flowing along the surface of semiconductor material 20, as measured and monitored by using voltmeter (potentiometer)-ammeter 27.

In Step (c), there is illuminating the exposed part of the surface contacted and wetted by the etching solution, during the negative biasing, for a period of time starting from initiation of the illuminating, such that the value of cathodic current density of the semiconductor material is significantly higher at the end of the illumination time period than at the beginning of the illumination time period.

Accordingly, with reference to FIG. 1, there is illuminating the exposed part of surface 20 contacted and wetted by etching solution 22, during the negative biasing of Step (b), for a period of time starting from initiation of the illuminating, such that the value of cathodic current density of semiconductor material 18 is significantly higher at the end of the illumination time period than at the beginning of the illumination time period.

For implementing the first preferred embodiment of the method of the present invention, electrochemical apparatus 10 includes specifically controlled and directed light source 16, light source power supply 38, optics 40, specifically controlled and directed-generated light 42, and, specifically controlled and directed-processed light 44. Light source power supply 38 supplies power to specifically controlled and directed light source 16, such that specifically controlled and directed light source 16 generates specifically controlled and directed-generated light 42. Specifically controlled and directed-generated light 42 is intentionally processed by specifically controlled and directed light source 16, and by optics 40, for forming specifically controlled and directed-processed light 44.

As exemplified in FIG. 1, preferably, specifically controlled and directed light source 16 is an artificial light source which generates specifically controlled and directed-generated light 42 in the form of non-ambient light. Specifically controlled and directed light source 16, preferably being an artificial light source, and optics 40, each includes any number of manually and/or automatically controllable devices, mechanisms, components, and/or elements, for example, light filters, light collimators, lenses, light amplifiers, light attenuators, three-dimensional translation and mounting/positioning stages, which are used for the intentional processing, for example, filtering, collimating, focusing, amplifying, and/or attenuating, and directing toward the active or working area of surface 20 of semiconductor material 18, of specifically controlled and directed-generated light 42. Specifically controlled and directed-processed light 44, in the form of processed non-ambient light, is thereby formed from the intentional processing of specifically controlled and directed-generated light 42, and is directed toward the active or working area surface 20 of semiconductor material 18, such that there is illuminating the exposed part of surface 20 contacted and wetted by etching solution 22, during the negative biasing of Step (b), for a period of time starting from initiation of the illuminating.

Specifically controlled and directed light source 16 is any type of controllable artificial light source which generates non-ambient light, and which, either alone or appropriately synchronized with operation of optics 40, is operable for manually and/or automatically controlling wavelength or frequency, and amplitude or intensity, of specifically controlled and directed-generated light 42, and therefore, of specifically controlled and directed-processed light 44, in the form of non-ambient light. Exemplary types of specifically controlled and directed light source 16 are halogen lamps, tungsten-halogen lamps, and dye lasers.

In Step (c) of the first preferred embodiment of the method of the present invention, it is to be fully understood that artificial light source 16 which generates the non-ambient type of specifically controlled and directed-generated light 42 is ‘not’, for example, one or more ceiling or table lamps or light fixtures, functioning for generating and transmitting surrounding or background (ambient) light, that illuminate a room or similar enclosure within which the first preferred embodiment of the method of the present invention is implemented.

In Step (c), preferably, the non-ambient light initially generated by specifically controlled and directed light source 16, that is, specifically controlled and directed-generated light 42, together with the non-ambient light formed by the intentional processing, that is, specifically controlled and directed-processed light 44, are specifically controlled and directed for producing light, in particular, processed non-ambient light, having an intensity of at least 0.01 watts per cm² at negatively biased semiconductor material surface 20 that is contacted and wetted by etching solution 22. More preferably, specifically controlled and directed-processed light 44, in the form of processed non-ambient light, has an intensity in a range of between about 0.5 watts per cm² and about 5.0 watts per cm² at negatively biased semiconductor material surface 20 that is contacted and wetted by etching solution 22.

Specifically controlled and directed-processed light 44, which is incident upon and illuminates negatively biased semiconductor material surface 20 that is contacted and wetted by etching solution 22, is light selected from the group consisting of polychromatic light, monochromatic light, poly- or multi-monochromatic light, and combinations thereof. In general, specifically controlled and directed-processed light 44 has a wavelength in a range of between about 100 nm and about 0.5 mm, and preferably, has a wavelength in a range of between about 250 nm and about 1500 nm, and more preferably, has a wavelength in a range of between about 280 nm and about 500 nm.

An exemplary polychromatic light is white light. An exemplary monochromatic light is selected from the group consisting of visible (VIS) spectrum monochromatic light, having a wavelength in the range of 350-750 nm, such as red light, blue light, or green light, and, invisible spectrum monochromatic light, such as ultra-violet (UV) light, having a wavelength in the range of 100-350 nm, or infrared (IR) light, having a wavelength in the range of 750 nm-0.5 mm. An exemplary poly- or multi-chromatic light is a combination of a plurality of at least two different previously listed exemplary monochromatic lights.

As previously stated above, prior to initiating illumination of the exposed part of surface 20 contacted and wetted by etching solution 22, the negative biasing of Step (b) is performed for a period of time of at least about one minute, during which time period semiconductor material 18 reaches a steady-state value of the applied negative potential, relative to standard reference electrode 26, and during which time period there is establishing a steady-state of cathodic current density, typically, having a baseline value of about zero A/cm² flowing along the surface of semiconductor material 20. Accordingly, immediately prior to initiating illumination of the exposed part of surface 20 contacted and wetted by etching solution 22, in accordance with Step (c), the value of cathodic current density of semiconductor material 18 is about zero A/cm².

Typically, within about one second of initiating illumination of the exposed part of surface 20 contacted and wetted by etching solution 22, during the negative biasing, the value of cathodic current density of semiconductor material 18 essentially instantaneously increases to a value corresponding to that at the beginning of the illumination time period. Thereafter, during the remainder of the duration of the illumination time period, the actual form and magnitude of increase in the value of cathodic current density of semiconductor material 18 from the value at the beginning of the illumination time period to a value at the end of the illumination time period, such that the value of cathodic current density of semiconductor material 18 is significantly higher at the end of the illumination time period than at the beginning of the illumination time period, for the given illumination time period, are functions of the combination of the several primary operating conditions and parameters of the negative potential dissolution (NPD) technique, such as type of semiconductor material 18; type, concentration, temperature, and flow rate, of etching solution 22; magnitude of the negative biasing; as well as by the intensity, wavelength, and duration, of illumination incident upon the negatively biased semiconductor material surface 20 exposed to etching solution 22.

Thus, in Step (c), there is subjecting the negatively biased semiconductor material surface 20 contacted and wetted by etching solution 22 to the specifically controlled and directed illumination by light, preferably, processed non-ambient light, in particular, specifically controlled and directed-processed light 44, as shown in FIG. 1, for a period of time, preferably, of at least about 60 seconds (one minute), starting from initiation of the illuminating, such that the value of cathodic current density of semiconductor material 18 is significantly higher at the end of the illumination time period than at the beginning of the illumination time period. The specifically controlled and directed illumination of semiconductor material surface 20 contacted and wetted by etching solution 22 while negatively biased to a potential more negative than minus sixty volts, is more preferably performed for a period of time of at least about 600 seconds (10 minutes), and may be performed for a period of time of more than about 5000 seconds (83 minutes), starting from initiation of the illuminating, such that the value of cathodic current density of semiconductor material 18 is significantly higher at the end of the illumination time period than at the beginning of the illumination time period.

In the first preferred embodiment of the method, the behavior of the value of cathodic current density of semiconductor material 18 being significantly higher at the end of the illumination time period than at the beginning of the illumination time period, for a given illumination time period of the specifically controlled and directed illumination of semiconductor material surface 20 contacted and wetted by etching solution 22 while negatively biased to a potential more negative than minus sixty volts, is a direct measure of the significant increase in the rate and extent of texturing of surface 20 of semiconductor material 18, and therefore, of the type of textured semiconductor material formed therefrom.

Although the ‘initial’ increase in the value of cathodic current density (A/cm²) of semiconductor material 18, and therefore, the initial increase in the rate and extent of texturing of surface 20 of semiconductor material 18, for example, as measured immediately starting from initiation of the illuminating, are clearly caused by the specifically controlled and directed illumination of semiconductor material surface 20 contacted and wetted by etching solution 22 while negatively biased to a potential more negative than minus sixty volts, the ‘final’ magnitude of increase in the value of cathodic current density of semiconductor material 18, and therefore, the final magnitude of increase in the rate and extent of texturing of surface 20 of semiconductor material 18, are controllable and significantly influenced by the combination of the several primary operating conditions and parameters of the negative potential dissolution (NPD) technique, such as type of semiconductor material 18; type, concentration, temperature, and flow rate, of etching solution 22; and, magnitude and duration of the negative biasing; as well as by the intensity, wavelength, and duration, of illumination incident upon the negatively biased semiconductor material surface 20 exposed to etching solution 22.

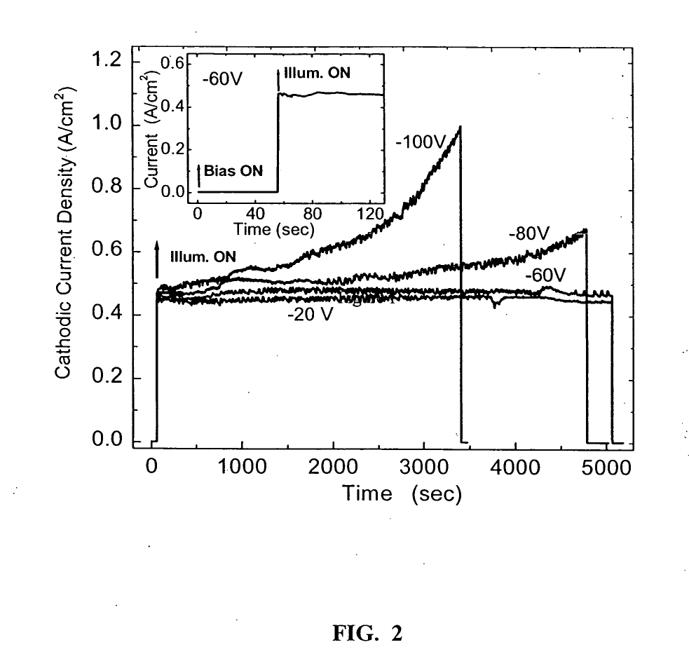

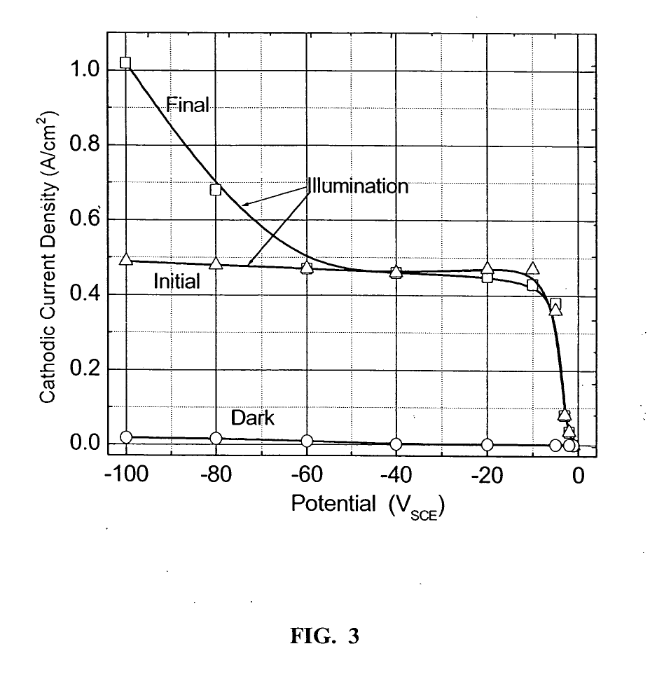

Exemplary implementation of the above illustratively described first preferred embodiment of a method for texturing a semiconductor material using the technique of negative potential dissolution (NPD), based on applying atypically highly negative (cathodic) potentials during conditions of wet etching, and a textured semiconductor material formed therefrom, according to the present invention, is illustratively described hereinbelow, in EXAMPLE 1, Texturing Polished <100> p-type Silicon Using Negative Potential Dissolution (NPD). Therein is clearly illustratively described in the Results and Discussion section, with reference to FIGS. 2 and 3, the behavior of the value of cathodic current density of semiconductor material 18 being significantly higher at the end of the illumination time period than at the beginning of the illumination time period, for a given illumination time period of the specifically controlled and directed illumination of semiconductor material surface 20 contacted and wetted by etching solution 22 while negatively biased to a potential more negative than minus sixty volts.

FIG. 2 is an empirically determined graphical plot of cathodic current density (A/cm²) measured as a function of time (sec), of an exemplary semiconductor material, polished <100> p-type silicon, during exposure to a potassium hydroxide (KOH) etching solution, 24 wt %, at 20° C., negative biasing at negative (cathodic) potentials of −20 V, −60 V, −80 V, and −100 V, relative to a standard calomel reference electrode (SCE), and specifically controlled and directed illumination by light, in particular, processed non-ambient light, having wavelengths in the range of between 280 nm and 500 nm, and providing an intensity of 2 watts per cm² at the negatively biased silicon surface, in accordance with the first preferred embodiment of the texturing method of the present invention.

FIG. 3 is an empirically determined graphical plot of cathodic current density (A/cm²) measured as a function of applied negative (cathodic) potential (V), at the conditions of the exemplary negative potential dissolution (NPD) with illumination procedure associated with FIG. 2, in accordance with the first preferred embodiment of the texturing method of the present invention.

The immediately preceding first preferred embodiment of the method of the present invention, for texturing a semiconductor material, is implemented for forming a corresponding textured semiconductor material.

Accordingly, with reference to exemplary electrochemical apparatus 10 schematically illustrated in FIG. 1, there is implementing Steps (a) through (c) of the above illustratively described first preferred embodiment of a method for texturing semiconductor material 18 using the technique of negative potential dissolution (NPD), based on applying atypically highly negative (cathodic) potentials during conditions of wet etching, for forming a corresponding textured semiconductor material therefrom.

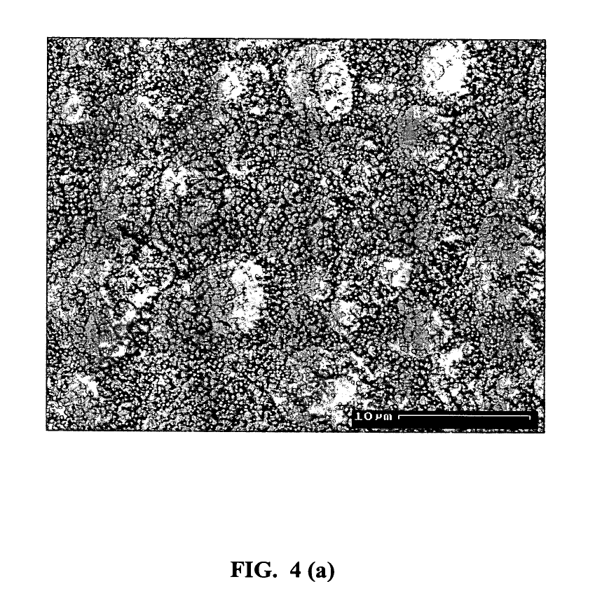

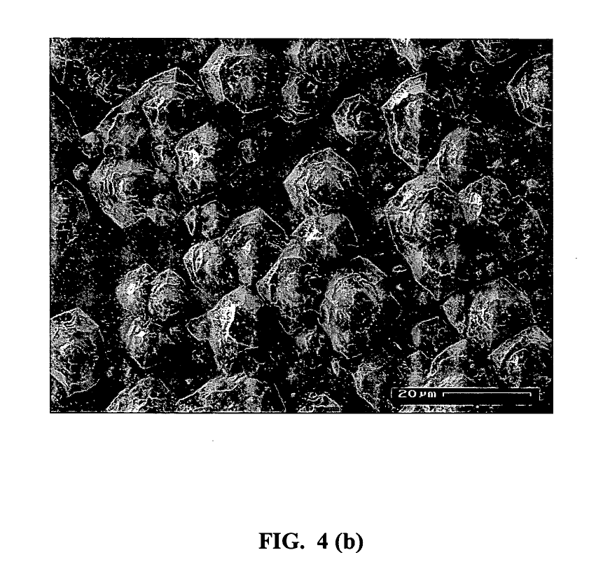

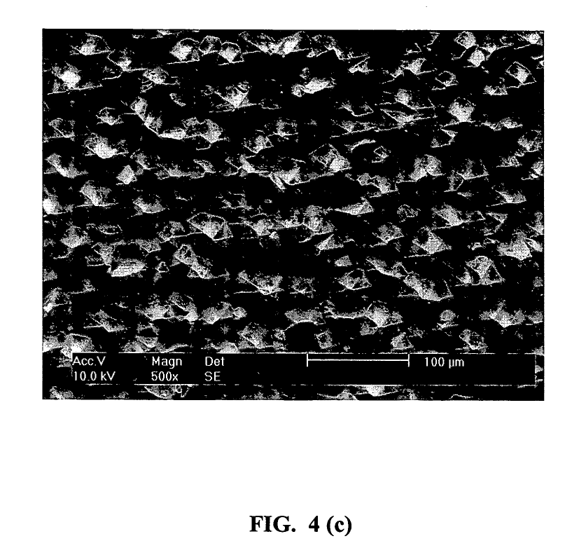

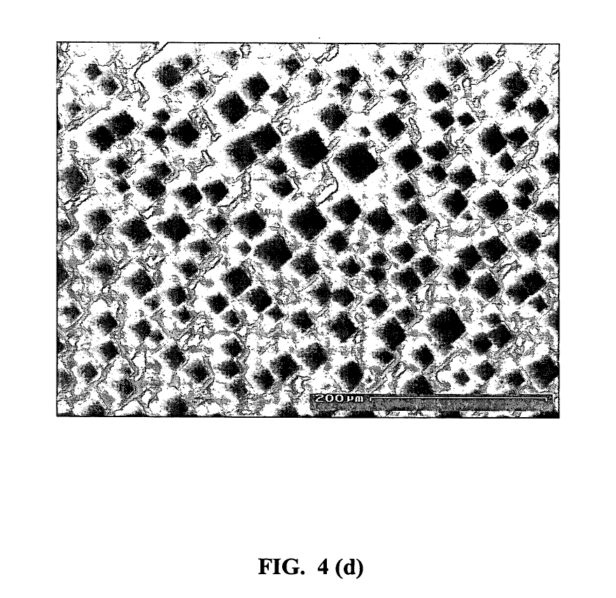

A variety of different exemplary embodiments, for example, pyramids and inverted pyramids, of an exemplary corresponding textured semiconductor material formed by implementing Steps (a) through (c) of the above illustratively described first preferred embodiment of the texturing method of the present invention, are illustratively described hereinbelow, in EXAMPLE 1, Texturing Polished <100> p-type Silicon Using Negative Potential Dissolution (NPD), with particular reference to FIGS. 4(a)-(d), along with reference to FIGS. 2 and 3.

FIGS. 4(a)-(d) are a sequential series of SEM micrographs of different embodiments of the textured surface of the exemplary <100> p-type silicon semiconductor material, each obtained at a different applied negative (cathodic) potential (V): (a) −40 V, (b) −60 V, (c) −80 V, and (d) −100 V, at the conditions of the exemplary negative potential dissolution (NPD) with illumination procedure associated with FIGS. 1 and 2, in accordance with the first preferred embodiment of the texturing method of the present invention.

As further described hereinbelow in more detail, an important highlight of the results obtained and shown in FIGS. 4(a)-(d), is that at applied negative potentials between about −40 V and −80 V, the morphology of at least part of the surface of the textured <100> p-type silicon surface is characterized by the presence of pyramids (FIGS. 4(a)-(c)). However, suprisingly, at an applied negative potential of about −100 V, a drastic change in the morphology takes place, such that the morphology of the textured <100> p-type silicon surface is characterized by the presence of inverted pyramids (FIG. 4(d)).

Immediately following is provided illustrative description of the second preferred embodiment of the method of the present invention, for texturing an as cut unpolished semiconductor material, using the technique of negative potential dissolution (NPD), and a textured as cut unpolished semiconductor material formed therefrom.

In Step (a) of the second preferred embodiment of the method of the present invention, for texturing an as cut unpolished semiconductor material, there is exposing at least part of a surface of the as cut unpolished semiconductor material to an etching solution, such that the exposed part of the surface is contacted and wetted by the etching solution.

In this preferred embodiment, the ‘as cut unpolished semiconductor material’ refers to a cut portion or section of a semiconductor material resulting from subjecting an uncut larger piece of the same semiconductor material to a cutting process, and which is unpolished, that is, having not been subjected to a polishing or similar type of surface smoothing process either before or after the cutting process. Such an as cut unpolished semiconductor material typically features a strongly damaged surface layer (having a thickness of on the order of about ten microns) characterized by any number of various different physicochemical types of surface defects and/or defect zones.

Step (a) of the second preferred embodiment of the method of the present invention, for texturing an as cut unpolished semiconductor material, is performed in the same manner as Step (a) of the previously illustratively described first preferred embodiment of the method of the present invention, for texturing a semiconductor material. In particular, with respect to use and operation of electrochemical flow-cell 12, and with respect to the type, concentration, temperature, and flow rate, of etching solution 22.

Accordingly, with reference to exemplary electrochemical apparatus 10 schematically illustrated in FIG. 1, there is exposing at least part of a surface 20 of an as cut unpolished semiconductor material 18 to etching solution 22, such that the exposed part of surface 20 is contacted and wetted by etching solution 22.

In exemplary electrochemical apparatus 10, sample holder 14 is for mounting and holding as cut unpolished semiconductor material 18, being subjected to the texturing method of the present invention, at least partly inside of electrochemical flow-cell 12. As cut unpolished semiconductor material 18 has an active or working area of, for example, about 1 cm², and, is mounted and held on sample holder 14 in a configuration for enabling exposure of at least part of the active or working area surface 20 of as cut unpolished semiconductor material 18 to etching solution 22, such that the exposed part of surface 20 is contacted and wetted by etching solution 22.

If as cut unpolished semiconductor material 18 has been masked and/or patterned prior to being mounted onto and held by sample holder 14, only those portions of the active or working area of surface 20 of as cut unpolished semiconductor material 18 which have not been masked and/or patterned are exposed to, and therefore, contacted and wetted by, etching solution 22. In such cases, ordinarily, the masking and/or patterning material, for example, Si₃N₄, or SiO₂, used for masking and/or patterning as cut unpolished semiconductor material 18 is either significantly less susceptible to etching solution 22 than is as cut unpolished semiconductor material 18, or is inert to etching solution 22. Moreover, it is noted that, sample holder 14 which is for mounting and holding as cut unpolished semiconductor material 18 during implementation of the texturing method of the present invention, may be of such a configuration so as to function as a mask.

For implementing the second preferred embodiment of the method, in general, the type of etching solution 22 is selected from the group consisting of an acidic etching solution, a neutral etching solution, a basic or alkaline etching solution, and a molten etching solution, as previously described hereinabove in Step (a) of the first preferred embodiment of the method.

For implementing the second preferred embodiment of the method, in general, the concentration of the solute in etching solution 22 is at least 0.001 M, as previously described hereinabove in Step (a) of the first preferred embodiment of the method. Preferably, the concentration of the solute in etching solution 22 is in a range of between about 8% (wt. solute/wt. solution) and about 50% (wt. solute/wt. solution).

For implementing the second preferred embodiment of the method, in general, the temperature of etching solution 22 is in a range of between about the freezing point of etching solution 22 and about the boiling point of etching solution 22, as previously described hereinabove in Step (a) of the first preferred embodiment of the method. For etching solution 22 being an aqueous etching solution, preferably, the temperature of etching solution 22 is in a range of between about 20° C. and about 90° C., and more preferably, in a range of between about 50° C. and about 90° C.

For implementing the second preferred embodiment of the method, in general, the flow rate of etching solution 22 contacting and wetting surface 20 of as cut unpolished semiconductor material 18, while flowing and circulating between etching solution reservoir 35 and electrochemical flow-cell 12 is in the range of between about 0 liter per minute and about 10 liters per minute. Preferably, the flow rate of etching solution 22 contacting and wetting surface 20 of as cut unpolished semiconductor material 18, while flowing and circulating between etching solution reservoir 35 and electrochemical flow-cell 12 is in a range of between about 1 mL per minute and about 2.5 liters per minute, and more preferably, in a range of between about 1 mL per minute and about 250 mL per minute.

During implementation of the second preferred embodiment of the method of the present invention using exemplary electrochemical apparatus 10, preferably, etching solution 22 flows at a pre-determined flow rate greater than zero, and is circulated between etching solution reservoir 35 and electrochemical flow-cell 12, via etching solution pump 34, electrochemical flow-cell inlet tube 36, and electrochemical flow-cell outlet tube 32. It is to be fully understood that the second preferred embodiment of the method of the present invention can also be implemented, using the same exemplary electrochemical apparatus 10, wherein the pre-determined flow rate of etching solution 22 is zero, that is, wherein etching solution 22 is essentially stationary (except for Brownian motion) inside electrochemical flow-cell 12 and along the exposed part of surface 20 of as cut unpolished semiconductor material 18 and therefore, is essentially stationary during the texturing of as cut unpolished semiconductor material 18 using the disclosed technique of negative potential dissolution (NPD).

The actual flow rate of etching solution 22 used for implementing the second preferred embodiment of the method of the present invention is selected according to the size or scale and throughput (production) of electrochemical apparatus 10 and of the overall texturing process, and according to the other primary operating conditions and parameters of the negative potential dissolution (NPD) technique, being the type of as cut unpolished semiconductor material 18; type, concentration, and temperature, of etching solution 22; and, magnitude and duration of the negative biasing (next Step (b)) applied to as cut unpolished semiconductor material 18.

Preferably, Step (a) is performed for a period of time of at least about one minute, and typically, for a period of time of about five minutes, prior to initiating negative biasing of as cut unpolished semiconductor material 18 in accordance with next Step (b), for enabling as cut unpolished semiconductor material 18, including the exposed part of surface 20 contacted and wetted by etching solution 22, to reach a steady-state value of an open circuit potential (OCP), relative to standard reference electrode 26, as measured and monitored by using the voltmeter function of voltmeter (potentiometer)-ammeter 27. Additionally, during this time period there is establishing a steady-state of the cathodic current density, typically, having a baseline value of about zero A/cm² flowing along the surface of as cut unpolished semiconductor material 20, as measured and monitored by using voltmeter (potentiometer)-ammeter 27.

In Step (b), there is negatively biasing the as cut unpolished semiconductor material to a negative potential of at least minus one volt relative to a standard reference electrode for a period of time, during which the as cut unpolished semiconductor material is illuminated by light having an intensity of less than 0.01 watts per cm², such that the value of cathodic current density of the as cut unpolished semiconductor material as a function of time during the time period initially increases to a maximum value, then decreases to a series of values each being significantly less than the maximum value.

With reference to exemplary electrochemical apparatus 10 schematically illustrated in FIG. 1, for implementing the second preferred embodiment of the method of the present invention, instead of including (that is, without the presence of) specifically controlled and directed light source 16, light source power supply 38, optics 40, specifically controlled and directed-generated light 42, and, specifically controlled and directed-processed light 44, (which components are included in exemplary electrochemical apparatus 10 used for implementing the first preferred embodiment of the method of the present invention), the electrochemical apparatus 10 includes non-specifically controlled and directed light source 50, and, non-specifically controlled and directed-generated (unprocessed) light 52.

Accordingly, in Step (b) of the second preferred embodiment of the method, there is negatively biasing as cut unpolished semiconductor material 18 to a negative potential of at least minus one volt relative to standard reference electrode 26 for a period of time, during which as cut unpolished semiconductor material 18 is illuminated by light, in particular, non-specifically controlled and directed-generated (unprocessed) light 52, having an intensity of less than 0.01 watts per cm², such that the value of cathodic current density of as cut unpolished semiconductor material 18 as a function of time during the time period initially increases to a maximum value, then decreases to a series of values each being significantly less than the maximum value.

In general, for performing Step (b) of the second preferred embodiment of the method of the present invention, there is negatively biasing as cut unpolished semiconductor material 18 to a negative potential in a range of between at least minus one volt and about minus one hundred volts relative to standard reference electrode 26. Preferably, there is negatively biasing as cut unpolished semiconductor material 18 to a negative potential in a range of between at least minus ten volts and about minus one hundred volts relative to standard reference electrode 26, and more preferably, there is negatively biasing as cut unpolished semiconductor material 18 to a negative potential in a range of between at least minus twenty volts and about minus fifty volts relative to standard reference electrode 26. The negative potential applied by negative biasing power supply 24, via primary electrode 25, to as cut unpolished semiconductor material 18, relative to standard reference electrode 26, is measured and monitored by using voltmeter (potentiometer)-ammeter 27.

With reference to FIG. 1, in general, non-specifically controlled and directed light source 50 is either an artificial light source, for example, a light source element, component, mechanism, or device, which is operatively connected to and powered by a power supply, for example, in the form of a ceiling or table lamp or light fixture, or is a natural light source, for example, the sun. Typically, non-specifically controlled and directed light source 50 is an artificial light source which continuously generates non-specifically controlled and directed-generated (unprocessed) light 52 in the form of unprocessed surrounding or background ambient light. The unprocessed surrounding or background ambient light is any surrounding or background light, which is ‘not’ processed (in contrast, as in the first preferred embodiment of the method, for example, by being filtered, collimated, focused, amplified, and/or attenuated, and directed toward the semiconductor material surface) by manual and/or automatic means. Accordingly, the initially generated ambient light remains ‘unprocessed ambient light’.

In Step (b) of the second preferred embodiment of the method of the present invention, it is to be fully understood that non-specifically controlled and directed light source 50 exclusively functions for continuously generating and transmitting non-specifically controlled and directed-generated (unprocessed) light 52 in the form of unprocessed surrounding or background ambient light, that illuminates a room or similar enclosure within which the second preferred embodiment of the method of the present invention is implemented. Non-specifically controlled and directed light source 50 which continuously generates the unprocessed surrounding or background ambient type of non-specifically controlled and directed-generated light 52 is ‘not’ specifically controlled and directed, and accordingly, non-specifically controlled and directed light source 50 continuously generates and transmits unprocessed surrounding or background ambient light which only generally illuminates the negatively biased as cut unpolished semiconductor material 18, including the exposed part of surface 20 contacted and wetted by etching solution 22.

By implementing the second preferred embodiment of the method, the non-specifically controlled and directed illumination of the negatively biased as cut unpolished semiconductor material 18 has no measurable affect upon the value of the cathodic current density (A/cm²) of as cut unpolished semiconductor material 18, or upon the rate and extent of texturing of as cut unpolished semiconductor material 18, and therefore, upon the type of textured as cut unpolished semiconductor material formed therefrom. Accordingly, so long as non-specifically controlled and directed-generated light 52 is in the form of unprocessed surrounding or background ambient light having an intensity of less than 0.01 watts per cm² incident upon the negatively biased as cut unpolished semiconductor material surface 20, the wavelength of non-specifically controlled and directed-generated light 52 is not an influencing parameter and is not relevant during performance of Step (b) of the second preferred embodiment of the method of the present invention.

As previously stated above, prior to initiating the negative biasing of as cut unpolished semiconductor material 18, the exposing of as cut unpolished semiconductor material 18 to etching solution 22 of Step (a) is performed for a period of time of at least about one minute, and typically, for a period of time of about five minutes, during which time period as cut unpolished semiconductor material 18, including the exposed part of surface 20 contacted and wetted by etching solution 22, reaches a steady-state value of an open circuit potential (OCP), relative to standard reference electrode 26, and during which time period there is establishing a steady-state of the cathodic current density, typically, having a baseline value of about zero A/cm² flowing along the surface of as cut unpolished semiconductor material 18. Accordingly, immediately prior to initiating negative biasing of as cut unpolished semiconductor material 18, in accordance with Step (c), the value of cathodic current density of semiconductor material 18 is about zero A/cm² During a given time period, widely varying, for example, in a range of between from as short as about 120 seconds (2 minutes) and to as long as about 2100 seconds (35 minutes), starting from the initiating of the negative biasing of as cut unpolished semiconductor material 18, and during which time period as cut unpolished semiconductor material 18 is illuminated by light, in particular, non-specifically controlled and directed-generated (unprocessed) light 52, having an intensity of less than 0.01 watts per cm², the value of cathodic current density of as cut unpolished semiconductor material 18 as a function of time during the time period, initially increases to a maximum value, then decreases to a series of values each being significantly less than the maximum value.

During the negative biasing time period, the actual form and magnitude of initial increase in the value of cathodic current density of as cut unpolished semiconductor material 18 to the maximum value, then decrease in the value of cathodic current density of as cut unpolished semiconductor material 18 to the series of values each being significantly less than the maximum value, are functions of the combination of the several primary operating conditions and parameters of the negative potential dissolution (NPD) technique, such as type of as cut unpolished semiconductor material 18; type, concentration, temperature, and flow rate, of etching solution 22; and magnitude of the negative biasing. This behavior of the value of cathodic current density of as cut unpolished semiconductor material 18 is ‘not’ a function of the intensity, wavelength, or duration, of illumination by light, in particular, non-specifically controlled and directed-generated (unprocessed) light 52, having an intensity of less than 0.01 watts per cm², incident upon the negatively biased as cut unpolished semiconductor material 18.

Thus, in Step (b), there is there is subjecting as cut unpolished semiconductor material 18 exposed to etching solution 22 to a negative potential in a range of between at least minus one volt and about minus one hundred volts, preferably, in a range of between at least minus ten volts and about minus one hundred volts, and more preferably, in a range of between at least minus twenty volts and about minus fifty volts, relative to standard reference electrode 26, for a period of time, preferably, in a range of between about 120 seconds (2 minutes) and about 2100 seconds (35 minutes), starting from the initiating of the negative biasing of as cut unpolished semiconductor material 18, and during which time period as cut unpolished semiconductor material 18 is illuminated by light, in particular, non-specifically controlled and directed-generated (unprocessed) light 52, having an intensity of less than 0.01 watts per cm², such that the value of cathodic current density of as cut unpolished semiconductor material 18 as a function of time during the time period, initially increases to a maximum value, then decreases to a series of values each being significantly less than the maximum value.

In the second preferred embodiment of the method, the behavior of the value of cathodic current density of as cut unpolished semiconductor material 18 as a function of time, during the negative biasing time period, initially increasing to a maximum value, then decreasing to a series of values each being significantly less than the maximum value, may be considered a direct measure of three different phenomena taking place on the exposed part of surface 20 contacted and wetted by etching solution 22, translating to a direct measure of the rate and extent of texturing of surface 20 of as cut unpolished semiconductor material 18, and therefore, of the type of textured as cut unpolished semiconductor material formed therefrom.

The first phenomenon, associated with the initial increase in the value of cathodic current density of as cut unpolished semiconductor material 18 to the maximum value, most likely corresponds to the existence of defects and/or defect zones along the exposed part of surface 20. As is well known in the art, an as cut unpolished semiconductor material typically features a strongly damaged surface layer (having a thickness of on the order of about ten microns) characterized by any number of various different physicochemical types of surface defects and/or defect zones. Accordingly, during the initial portion of the negative biasing time period, starting from the initiating of the negative biasing of as cut unpolished semiconductor material 18, the initial increase in the value of cathodic current density of as cut unpolished semiconductor material 18 to the maximum value, is a direct measure of the existence of defects and/or defect zones located along the topology or morphology of the exposed part of surface 20 of as cut unpolished semiconductor material 18.

The second and third phenomena, associated with the decrease in the value of cathodic current density of as cut unpolished semiconductor material 18 to a series of values each being significantly less than the maximum value, most likely correspond to two parallel surface processes simultaneously taking place: (i) removal of defects and/or defect zones located along the topology or morphology of the exposed part of surface 20 of as cut unpolished semiconductor material 18, and (ii) texturing along the topology or morphology of the exposed part of surface 20 of as cut unpolished semiconductor material 18.

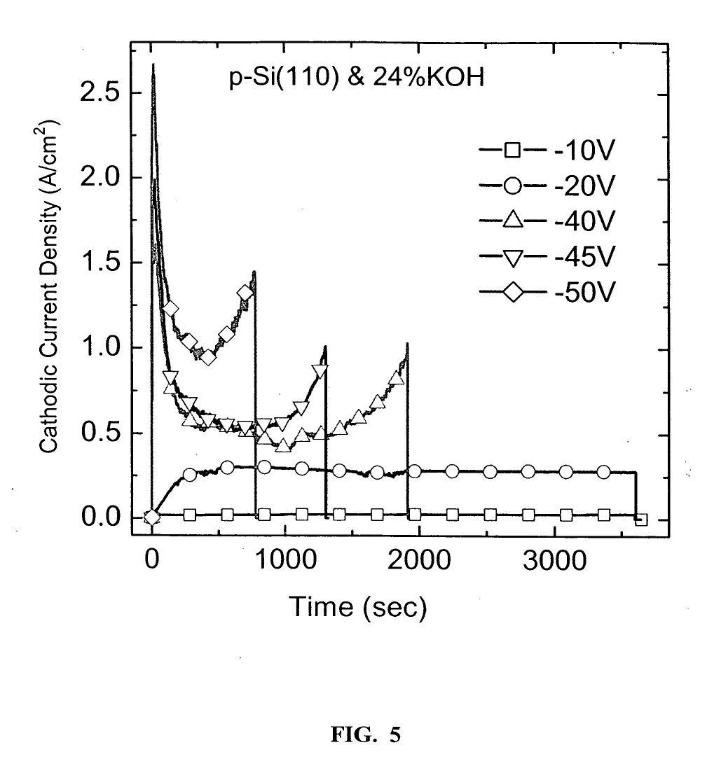

Exemplary implementation of the above illustratively described second preferred embodiment of a method for texturing an as cut unpolished semiconductor material using the technique of negative potential dissolution (NPD), based on applying atypically highly negative (cathodic) potentials during conditions of wet etching, and a textured as cut unpolished semiconductor material formed therefrom, according to the present invention, is illustratively described hereinbelow, in EXAMPLE 2, Texturing ‘As Cut Unpolished’ <110> and <111> p-type Silicon Using Negative Potential Dissolution (NPD). Therein is clearly illustratively described in the Results and Discussion section, with reference to FIGS. 5, 6, 8, and 9, the behavior of the value of cathodic current density of as cut unpolished semiconductor material 18 as a function of time, during the negative biasing time period, initially increasing to a maximum value, then decreasing to a series of values each being significantly less than the maximum value, as a result of negatively biasing as cut unpolished semiconductor material 18 to a negative potential of at least minus one volt relative to standard reference electrode 26 for a period of time, during which as cut unpolished semiconductor material 18 is illuminated by light having an intensity of less than 0.01 watts per cm², corresponding to implementation at ‘dark’ conditions.

FIG. 5 is an empirically determined graphical plot of cathodic current density (A/cm²) measured as a function of time (sec), of an exemplary as cut unpolished semiconductor material, as cut unpolished <110> p-type silicon wafer, during exposure to a potassium hydroxide (KOH) etching solution, 24 wt %, at 20° C., negative biasing at negative (cathodic) potentials of −10 V, −20 V, −40 V, −45 V, and −50 V, relative to a standard calomel reference electrode (SCE), during ‘dark’ conditions of non-specifically controlled and directed illumination by light, in particular, in the form of unprocessed surrounding or background ambient light having an intensity of less than 0.01 watts per cm² incident upon the negatively biased as cut unpolished silicon surface, in accordance with the second preferred embodiment of the texturing method of the present invention.

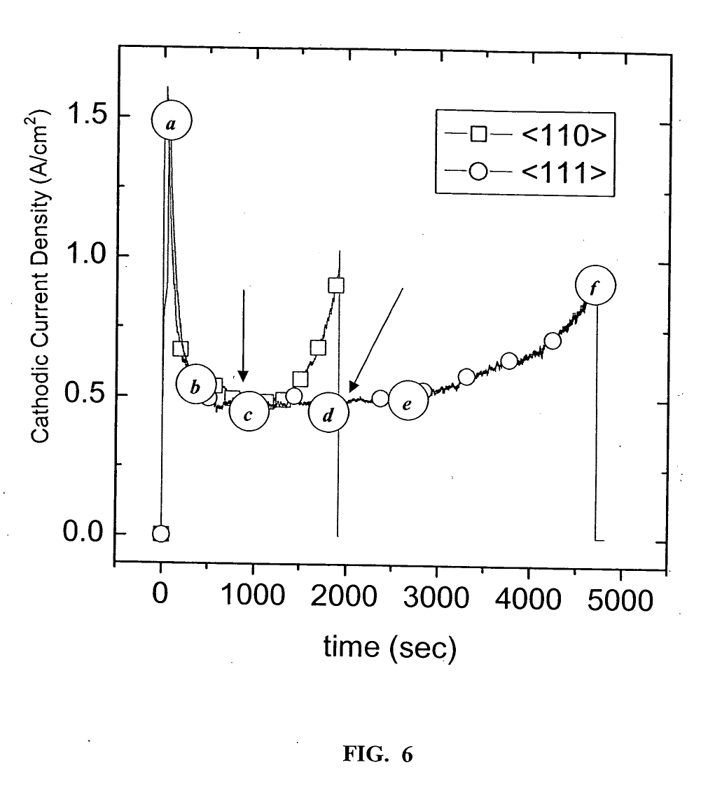

FIG. 6 is an empirically determined graphical plot of cathodic current density (A/cm²) measured as a function of time (sec), of exemplary as cut unpolished semiconductor materials, as cut unpolished <110> p-type silicon wafer, and as cut unpolished <111> p-type silicon wafer, during separately exposing each to a potassium hydroxide (KOH) etching solution, 24 wt %, at 20° C., negative biasing at a negative (cathodic) potential of −40 V, and −45 V, respectively, relative to a standard calomel reference electrode (SCE), during ‘dark’ conditions of non-specifically controlled and directed illumination by light, in particular, in the form of unprocessed surrounding or background ambient light having an intensity of less than 0.01 watts per cm² incident upon the negatively biased as cut unpolished silicon surface, in accordance with the second preferred embodiment of the texturing method of the present invention.

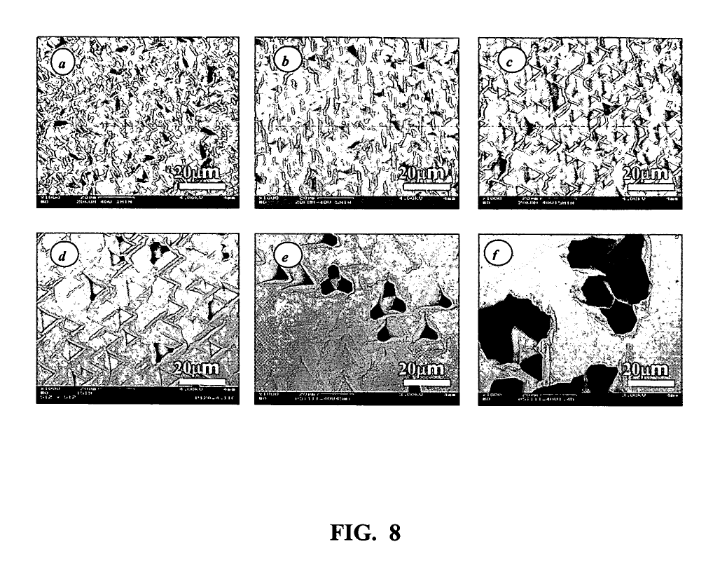

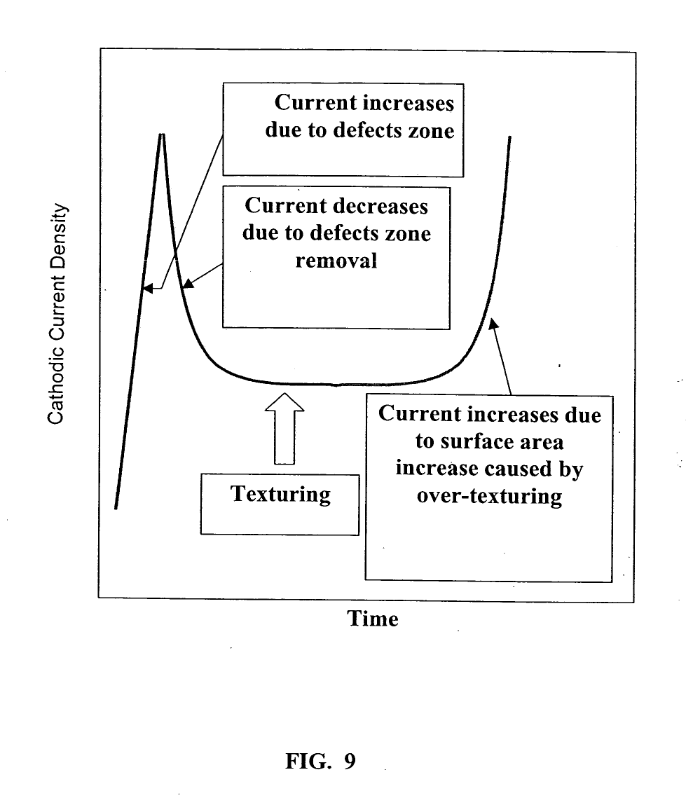

FIGS. 8(a)-(f) are a sequential time series of HRSEM micrographs of the surface of the exemplary as cut unpolished <111> p-type silicon wafer during the exemplary negative potential dissolution (NPD) procedure associated with FIG. 6, obtained at the same indicated times during the negative biasing (−45 V) time period: (a) 60 sec, (b) 300 sec, (c) 900 sec, (d) 1800 sec, (e) 2700 sec, and (f) 5100 sec, in accordance with the second preferred embodiment of the texturing method of the present invention. FIG. 9 is a graphical plot of cathodic current density (A/cm²) as a function of time (sec), depicting an exemplary proposed model graphically illustrating the multi-phenomenological behavior of the value of cathodic current density of an as cut unpolished semiconductor material as a function of time, during the negative biasing time period, during dark conditions, in accordance with the second preferred embodiment of the texturing method of the present invention.

The immediately preceding second preferred embodiment of the method of the present invention, for texturing an as cut unpolished semiconductor material, is implemented for forming a corresponding textured as cut unpolished semiconductor material.

Accordingly, with reference to exemplary electrochemical apparatus 10 schematically illustrated in FIG. 1, there is implementing Steps (a) through (b) of the above illustratively described second preferred embodiment of a method for texturing as cut unpolished semiconductor material 18 using the technique of negative potential dissolution (NPD), based on applying atypically highly negative (cathodic) potentials during conditions of wet etching, for forming a corresponding textured as cut unpolished semiconductor material therefrom.

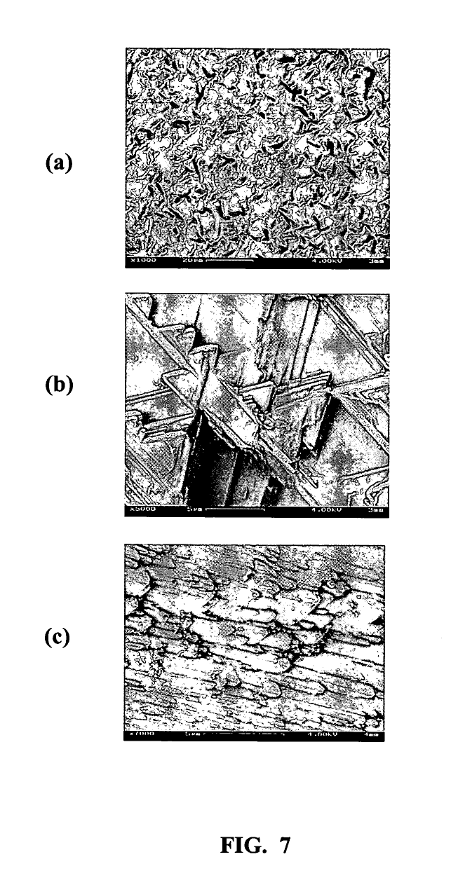

Exemplary embodiments of exemplary corresponding textured as cut unpolished semiconductor materials formed by implementing Steps (a) through (b) of the above illustratively described second preferred embodiment of the texturing method of the present invention, are illustratively described hereinbelow, in EXAMPLE 2, Texturing ‘As Cut’ Unpolished <110> and <111> p-type Silicon Using Negative Potential Dissolution (NPD), with particular reference to FIGS. 7(a)-(c), along with reference to FIG. 6.

FIGS. 7(a)-(c) are a series of HRSEM micrographs of exemplary embodiments of the surface of the exemplary as cut unpolished semiconductor materials, as cut unpolished <110> p-type silicon wafer, and as cut unpolished <111> p-type silicon wafer: (a) pristine as cut unpolished <110> p-type silicon without subjection to wet etching and negative biasing; and, (b) textured as cut unpolished <111> p-type silicon and (c) textured as cut unpolished <110> p-type silicon, obtained at the minima values (indicated by the arrows in FIG. 6) of cathodic current density as a function of time, during the exemplary negative potential dissolution (NPD) procedure associated with FIG. 6, in accordance with the second preferred embodiment of the texturing method of the present invention.

As further described hereinbelow in more detail, an important highlight of the results obtained and shown in FIGS. 7(a) and (b), is that at relatively large applied negative potentials, for example, more negative than −40 V, the morphology of at least part of the surface of the textured as cut unpolished <110> p-type silicon surface is characterized by the presence of long prisms (FIG. 7(c)). However, at the same conditions, the morphology of at least part of the surface of the textured as cut unpolished <111> p-type silicon surface is characterized by the presence of coined triangles (FIG. 7 (b)). Accordingly, the specific type of morphology of the textured as cut unpolished silicon is a function of the crystal orientation of the as cut unpolished silicon.

In an alternative second preferred embodiment of the method of the present invention, described hereinbelow, the as cut unpolished semiconductor material is ‘not’ illuminated by light during the step, in particular, during Step (b), of the negative biasing of the as cut unpolished semiconductor material to a negative potential of at least minus one volt relative to a standard reference electrode for a period of time. Accordingly, with reference to exemplary electrochemical apparatus 10 illustrated in FIG. 1, non-specifically controlled and directed light source 50, and therefore, non-specifically controlled and directed-generated light 52, which are included in the description of the second preferred embodiment of the method, hereinabove, are ‘not’ included in the description of the alternative second preferred embodiment of the method of the present invention. Thus, it is as if the alternative second preferred embodiment of the method is implemented in ‘actual darkness’ at ‘dark’ conditions, without any type of light source, and therefore, without any type of illumination of the as cut unpolished semiconductor material by any type of light. For completeness of describing the present invention, the main steps of the alternative second preferred embodiment of the method of the present invention are illustratively described hereinbelow.

In Step (a) of the alternative second preferred embodiment of the method of the present invention, for texturing an as cut unpolished semiconductor material, there is exposing at least part of a surface of the as cut unpolished semiconductor material to an etching solution, such that the exposed part of the surface is contacted and wetted by the etching solution.

Step (a) of the alternative second preferred embodiment of the method of the present invention, for texturing an as cut unpolished semiconductor material, is performed in the same manner as Step (a) of the immediately preceding illustratively described second preferred embodiment of the method of the present invention, for texturing an as cut semiconductor material. In particular, with respect to use and operation of electrochemical flow-cell 12, and with respect to the type, concentration, temperature, and flow rate, of etching solution 22. Accordingly, all actions, conditions, and parameters, used for exposing as cut unpolished semiconductor material 18 to etching solution 22 in Step (a) of the alternative second preferred embodiment of the method for texturing an as cut unpolished semiconductor material, at dark conditions, are used in the same manner as for performing Step (a) of the immediately preceding illustratively described second preferred embodiment of the method of the present invention, for texturing an as cut semiconductor material.

In Step (b), there is negatively biasing the as cut unpolished semiconductor material to a negative potential of at least minus one volt relative to a standard reference electrode for a period of time, such that the value of cathodic current density of the as cut unpolished semiconductor material as a function of time during the time period initially increases to a maximum value, then decreases to a series of values each being significantly less than the maximum value.

With reference to exemplary electrochemical apparatus 10 schematically illustrated in FIG. 1, for implementing the alternative second preferred embodiment of the method of the present invention, at dark conditions, in addition to not including (that is, without the presence of) specifically controlled and directed light source 16, light source power supply 38, optics 40, specifically controlled and directed-generated light 42, and, specifically controlled and directed-processed light 44, (which components are included in exemplary electrochemical apparatus 10 used for implementing the first preferred embodiment of the method of the present invention), the electrochemical apparatus 10 also does not include non-specifically controlled and directed light source 50, and, non-specifically controlled and directed-generated (unprocessed) light 52, (which components are included in exemplary electrochemical apparatus 10 used for implementing the second preferred embodiment of the method of the present invention).

Accordingly, electrochemical apparatus 10 used for implementing the alternative second preferred embodiment of the method of the present invention, at dark conditions, consists essentially of the main components: electrochemical flow-cell 12, sample holder 14, flowable etching solution 22, electrochemical flow-cell inlet tube 36, electrochemical flow-cell outlet tube 32, etching solution pump 34, etching solution reservoir 35, negative biasing power supply 24, primary electrode 25, standard reference electrode 26, dual function voltmeter (potentiometer)-ammeter 27, capillary tube 28, counter-electrode 30, and timer 60.

Thus, in Step (b) of the alternative second preferred embodiment of the method, there is negatively biasing as cut unpolished semiconductor material 18 to a negative potential of at least minus one volt relative to standard reference electrode 26 for a period of time, such that the value of cathodic current density of as cut unpolished semiconductor material 18 as a function of time during the time period initially increases to a maximum value, then decreases to a series of values each being significantly less than the maximum value.

Taking into account that in the alternative second preferred embodiment of the method of the present invention, as cut unpolished semiconductor material 18 is ‘not’ illuminated by light during Step (b) of the negative biasing of as cut unpolished semiconductor material 18 to a negative potential of at least minus one volt relative to standard reference electrode 26 for a period of time, herein, all other actions, conditions, and parameters, used for performing the negative biasing of as cut unpolished semiconductor material 18 in Step (b) of the alternative second preferred embodiment of the method for texturing an as cut unpolished semiconductor material, at dark conditions, are used in the same manner as for performing Step (b) of the immediately preceding illustratively described second preferred embodiment of the method of the present invention, for texturing an as cut semiconductor material. In particular, with respect to use and operation of electrochemical flow-cell 12, and with respect to use and operation of negative biasing power supply 24, primary electrode 25, standard reference electrode 26, dual function voltmeter (potentiometer)-ammeter 27, capillary tube 28, counter-electrode 30, and timer 60, which are particularly relevant to performing the negative biasing of as cut unpolished semiconductor material 18 of Step (b).

Moreover, all non-illumination related aspects, features, characteristics, and results, relating to and obtained by performing the negative biasing in Step (b) of the immediately preceding illustratively described second preferred embodiment of the method for texturing an as cut unpolished semiconductor material are herein, fully applicable to Step (b) of the alternative second preferred embodiment of the method of the present invention, for texturing an as cut semiconductor material.

Accordingly, in the alternative second preferred embodiment of the method, the behavior of the value of cathodic current density of as cut unpolished semiconductor material 18 as a function of time, during the negative biasing time period, initially increasing to a maximum value, then decreasing to a series of values each being significantly less than the maximum value, may be considered a direct measure of the same three different phenomena taking place on the exposed part of surface 20 contacted and wetted by etching solution 22, as previously described above in the description of the second preferred embodiment of the method, translating to a direct measure of the rate and extent of texturing of surface 20 of as cut unpolished semiconductor material 18, and therefore, of the type of textured as cut unpolished semiconductor material formed therefrom.

Thus, the first phenomenon, associated with the initial increase in the value of cathodic current density of as cut unpolished semiconductor material 18 to the maximum value, most likely corresponds to the existence of defects and/or defect zones along the exposed part of surface 20. The second and third phenomena, associated with the decrease in the value of cathodic current density of as cut unpolished semiconductor material 18 to a series of values each being significantly less than the maximum value, most likely correspond to two parallel surface processes simultaneously taking place: (i) removal of defects and/or defect zones located along the topology or morphology of the exposed part of surface 20 of as cut unpolished semiconductor material 18, and (ii) texturing along the topology or morphology of the exposed part of surface 20 of as cut unpolished semiconductor material 18.

Exemplary implementation of the above illustratively described alternative second preferred embodiment of a method for texturing an as cut unpolished semiconductor material using the technique of negative potential dissolution (NPD), based on applying atypically highly negative (cathodic) potentials during conditions of wet etching, and a textured as cut unpolished semiconductor material formed therefrom, at dark conditions, according to the present invention, is the same as that of the immediately preceding illustratively described second preferred embodiment of the method for texturing an as cut unpolished semiconductor material. In particular, hereinbelow, in EXAMPLE 2, Texturing ‘As Cut Unpolished’ <110> and <111> p-type Silicon Using Negative Potential Dissolution (NPD), in the Results and Discussion section, with reference to FIGS. 5, 6, 8, and 9, wherein there is illustrative description of the behavior of the value of cathodic current density of as cut unpolished semiconductor material 18 as a function of time, during the negative biasing time period, initially increasing to a maximum value, then decreasing to a series of values each being significantly less than the maximum value, as a result of negatively biasing as cut unpolished semiconductor material 18 to a negative potential of at least minus one volt relative to standard reference electrode 26 for a period of time.

The immediately preceding alternative second preferred embodiment of the method of the present invention, for texturing an as cut unpolished semiconductor material, is implemented for forming a corresponding textured as cut unpolished semiconductor material.

Accordingly, with reference to exemplary electrochemical apparatus 10 schematically illustrated in FIG. 1, there is implementing Steps (a) through (b) of the above illustratively described alternative second preferred embodiment of a method for texturing as cut unpolished semiconductor material 18 using the technique of negative potential dissolution (NPD), based on applying atypically highly negative (cathodic) potentials during conditions of wet etching, for forming a corresponding textured as cut unpolished semiconductor material therefrom.

Exemplary embodiments of exemplary corresponding textured as cut unpolished semiconductor materials formed by implementing Steps (a) through (b) of the above illustratively described alternative second preferred embodiment of the texturing method of the present invention, are the same as those of the immediately preceding illustratively described second preferred embodiment of the method for texturing an as cut unpolished semiconductor material. In particular, as illustratively described hereinbelow, in EXAMPLE 2, Texturing ‘As Cut Unpolished’ <110> and <111> p-type Silicon Using Negative Potential Dissolution (VPD), with particular reference to FIGS. 7(a)-(c), along with reference to FIG. 6.

Above described novel and inventive features and aspects, and advantages thereof, of the present invention further become apparent to one ordinarily skilled in the art upon examination of the following examples, which are not intended to be limiting. Additionally, each of the various embodiments and aspects of the present invention as delineated herein above and as claimed in the claims section below finds experimental support in the following examples.

### EXAMPLES

Reference is now made to the following examples, which together with the above descriptions, illustrate the invention in a non-limiting fashion.

Exemplary implementation of the above illustratively described first preferred embodiment of a method for texturing a semiconductor material using the technique of negative potential dissolution (NPD), based on applying atypically highly negative (cathodic) potentials during conditions of wet etching, and a textured semiconductor material formed therefrom, according to the present invention, is illustratively described hereinbelow, in EXAMPLE 1, Texturing Polished <100> p-type Silicon Using Negative Potential Dissolution (NPD).

Exemplary implementation of the above illustratively described second preferred embodiment of a method, and the alternative thereof, for texturing an as cut unpolished semiconductor material using the technique of negative potential dissolution (NPD), based on applying atypically highly negative (cathodic) potentials during conditions of wet etching, and a textured as cut unpolished semiconductor material formed therefrom, according to the present invention, is illustratively described hereinbelow, in EXAMPLE 2, Texturing ‘As Cut Unpolished’ <110> and <111> p-type Silicon Using Negative Potential Dissolution (NPD).

It is noted that the experimental work illustratively described in each of Example 1 and Example 2, hereinbelow, was performed using the exemplary electrochemical apparatus described and illustrated in FIG. 1 in the same inventors' U.S. Pat. No. 6,521,118, entitled: “Semiconductor Etching Process And Apparatus”, the teachings of which are incorporated by reference as if fully set forth herein. That apparatus is the basis of, and generally corresponds to, exemplary electrochemical apparatus 10 schematically illustrated in FIG. 1 of the present invention, used for implementing each of the first preferred embodiment, the second preferred embodiment and the alternative thereof, of the method of the present invention.

### Example 1

### Texturing Polished <100> p-type Silicon Using Negative Potential Dissolution (NPD)

Experimental

The effect of applying the Negative Potential Dissolution (NPD) technique on polished p-type silicon (orientation <100>, 8-12 Ω-cm) topography was studied using a potassium hydroxide (KOH) etching solution, 24 wt. %, at 20° C. Experiments were conducted using an electrochemical apparatus (10 in FIG. 1, as described above) with an electrochemical flow-cell (12 in FIG. 1) containing a Teflon sample holder equipped with an O-ring. The working area of the silicon electrode was 1 cm². In order to avoid stagnation and warming of the etching electrolyte, 4.5 litters of NaOH solution were used. The etching solution was circulated between the electrochemical cell (volume of 1.5 liters) and a reservoir vessel (volume of 3 liters), by a flow controllable peristaltic pump, at a pre-determined flow rate in the range of between 1 mL per minute and 250 mL per minute. An HP 762 power supply was used in a constant potential mode. The negative (cathodic) potentials applied to the tested silicon electrodes were measured with the use of a Luggin capillary and a saturated calomel reference electrode (SCE), while a platinum wire was used as a counter electrode.

In order to remove the initial oxide film from the silicon surface, the silicon electrode was exposed to the potassium hydroxide (KOH) etching solution at open circuit potential (OCP). The cathodic polarization was applied only when the potential of the silicon sample reached a steady-state value, usually about −1.15 V. Following a cathodic polarization for a time period of 1 minute, the silicon surface was illuminated in the wavelength range between 280 and 500 nm. The intensity and diameter of the light beam were 2 watts and 0.5 cm², respectively. Subsequent to the NPD process, the surface of the tested silicon was evaluated using scanning electron microscopy (SEM, LEO-982 Geminate FEG-HRSEM).

Results and Discussion

Tested p-type silicon electrodes were subjected to negative (cathodic) biasing with and without illumination. In each case, cathodic polarization was accompanied by evolution of hydrogen gas. FIG. 2 is an empirically determined graphical plot of cathodic current density (A/cm²) measured as a function of time (sec), of the polished <100> p-type silicon, during exposure to a potassium hydroxide (KOH) etching solution, 24 wt %, at 20° C., negative biasing at negative (cathodic) potentials of −20 V, −60 V, −80 V, and −100 V, relative to a standard calomel reference electrode (SCE), and specifically controlled and directed illumination by light, in particular, processed non-ambient light, having wavelengths in the range of between 280 nm and 500 nm, and providing an intensity of 2 watts per cm² at the negatively biased silicon surface. FIG. 2 shows cathodic current density transient curves obtained from the illuminated polished <100> p-type silicon at different applied negative potentials. Since p-type silicon is in depletion or inversion under cathodic polarization, the value of cathodic current density remained very low at all the cathodic potentials down to −100 V. A sudden increase in the value of cathodic current density was observed once illumination was switched on, in addition to the cathodic polarization (FIG. 2, inset).

The value of cathodic current density jumped immediately subsequent to the illumination and reached certain initial values. Value of cathodic current density obtained immediately after illumination were dependent on the applied negative potentials only for negative potentials more negative than −10 V. At these atypically highly negative potentials, the value of cathodic current density increased with any shift in the applied negative potential, as illustrated by the “Initial” curve in FIG. 3, an empirically determined graphical plot of cathodic current density (A/cm²) measured as a function of applied negative (cathodic) potential (V), at the conditions of the exemplary negative potential dissolution (NPD) with illumination procedure associated with FIG. 2. At potentials more negative than −10 V, the initial value of cathodic current density measured immediately after illuminating remained almost constant at 0.46-0.47 A/cm², in a wide potential range down to −100 V.

Two characteristic negative potential regions were observed, each characterized by a different profile of values of cathodic current density, measured during sample illumination. As shown in FIG. 2, down to −60 V, the value of cathodic current density remained practically independent of the applied potential during an exposure time of about 5000 seconds. At negative potentials more negative than −60 V, the value of cathodic current density gradually increased. The value of cathodic current density measured from the silicon sample, during exposure at a negative potential of −80 V, slowly increased from 0.48 to 0.68 A/cm². However, another increase in the measured value of cathodic current density was detected when the applied negative potential was shifted to more negative values. FIG. 2 shows that the value of cathodic current density measured from the silicon electrode during NPD at −100 V increased faster, from −0.48 to 1 A/cm² during a time period of 3300 sec, than the value of cathodic current density measured at the negative potential of-80 V.

The values of the initial cathodic current density measured immediately after illuminating the silicon electrodes (“Initial” curve), and at the end-point of each experiment (“Final” curve) are summarized in FIG. 3. The difference between the initial and the final values of cathodic current density was detected only in the potential range more negative than −60 V. Once a shift in the applied potential in the negative direction is maintained, this difference dramatically increased. At potentials less negative than −60 V, the initial and final values of cathodic current density practically coincided.

Data summarizing the measured etching rates (μm/min) obtained from weight loss and etching time measurements during different applied cathodic potentials are as follows:

During Dark Conditions: 0.045 μm/min at open circuit potential (OCP), and 0.027 μm/min at −40 V.

During Illumination Conditions: 0.104 μm/min at −40 V, 0.207 μm/min at −60 V, 0.33 μm/min at −80 V, and 0.883 μm/min at −100 V.

Si etch rate obtained with illumination at different applied potentials was not high. The etch rate measured at −40 V was 0.104 μm/min, while at −100 V, the etch rate reached a value of 0.883 μm/min. On the contrary, Si etch rate obtained at OCP (without applied potential and illumination) was only 0.045 μm/min. No effect of the applied cathodic potential on Si etch rate was observed without illumination. The values obtained for Si etch rate at different applied potentials, up to −100 V, without illumination, were very similar to the etch values obtained at OCP.

Not only the cathodic current density transient, but also the topography of the silicon surface was found to be strongly affected by the cathodic polarization. FIGS. 4(a)-(d) are a sequential series of SEM micrographs of different embodiments of the textured surface of the <100> p-type silicon semiconductor material, each obtained at a different applied negative (cathodic) potential (V): (a) −40 V, (b) −60 V, (c) −80 V, and (d) −100 V, at the conditions of the exemplary negative potential dissolution (NPD) with illumination procedure associated with FIG. 2. These SEM micrographs of silicon electrodes were taken after the Si NPD process was completed. The micrographs were obtained subsequent to p-type Si treatment with 24% KOH at 20° C., at potentials ranging from −40 to −100 V. As can be seen, the various classes of textured surface produced on silicon substrate are dependent on the applied cathodic potential.

FIG. 4(a) shows that the silicon surface exposed at −40 V was fully covered with very small pyramids with base length dimensions significantly smaller than 1 μm. Sporadic pyramids with larger dimensions, with base lengths of about 4 μm, are also detected on the treated surface. The morphology developed at the silicon surface is noticeably different at the potential of −60 V (FIG. 4(b)). At this potential condition, the small pyramids previously observed in FIG. 4(a), with dimensions smaller than 1 μm, completely disappeared and the treated silicon surface became covered with significantly larger pyramids, with base lengths of about 20 μm. However, the textured surface obtained at this potential did not result in absolute pyramidal coverage of the silicon substrate. As is seen in the SEM micrograph, only 50% of the silicon surface was covered with pyramids, while the non-textured area remained a smooth surface.

With a further reduction in the potential to −80 V (FIG. 4(c)), similar pyramid structures were detected, as was observed at the potential of −60 V. However, unlike the morphology developed at −60 V, at this potential a complete coverage (with pyramid structures) of the silicon surface was obtained. Bare sites on the silicon surface treated at the potential of −80 V were unidentifiable. It is noted that at the apex of some pyramids, the appearance of holes in the shape of an inverse (concave) pyramid were also observed.

A drastic change in the surface morphology was detected with an additional negative shift in the applied potential. At a potential of −100 V (FIG. 4(d)), the formation of inverted pyramids was observed. As is seen therein, the inverted pyramids fully cover the silicon surface. Thus, the changes in the cathodic current transients, in particular, the rapid increase in the current detected during silicon texturing under the conditions of −80 and −100 V may be attributed to the formation of well established pyramidal morphology (−80 V) or to the configuration of inverted pyramid morphology (−100 V). Therefore, increase in the values of cathodic current density during the negative biasing time period at these potentials may be associated with an overall surface area increase at these atypically highly negative potentials. This was especially significant in the case of the formation of inverted pyramids.

It is well known in the art of silicon etching, that formation of pyramidal morphology is usually associated with silicon etching performed at open circuit potential (OCP). The formation of this type of textured structure by using NPD is not clear, and different hypotheses can be presented. Pyramidal texturing is frequently attributed to the combination of anisotropic silicon etching and hydrogen bubbles evolved during the etching reaction, for example, as described by D. L. King and M. E. Buck, in 22nd IEEE Photovoltaics Specialists Conf., vol. 1, p. 303, 1991. It was postulated that hydrogen bubbles adhere to the silicon surface and their masking effect results in a lateral etching action.

However, considering silicon etching under NPD conditions, the effect of evolved hydrogen bubbles on silicon texturing can not be taken for granted. It was shown herein, in FIG. 2, that the value of cathodic current density measured at the initial stages of the NPD process (with the combination of negative applied potentials and illumination) was actually constant over a wide range of potentials from −20 V to −100 V. If indeed the value of cathodic current density is only associated with the hydrogen formation process (water reduction), it is reasonable to assume that the rate of hydrogen evolution during the initial stages of any applied negative potential is also steady. Taking into account equal rates of hydrogen evolution during the initial stages of silicon NPD (in a wide range of applied negative potentials), it is highly difficult to explain the dramatic effect of the applied potential on silicon surface morphology using only the model of evolved hydrogen bubbles. The appearance of various morphological characteristics on the silicon surface appears to be only a function of the applied negative potential. Main operating parameters of, and conditions relating to, alkaline etching solution concentration, time, temperature, illumination and surface defects, apparently influence, in varying degrees, the Si texturing under cathodic polarization. An accurate explanation of the NPD effect on Si texturing is apparently based on a detailed understanding of the silicon NPD mechanism.

### Example 2

Texturing ‘As Cut Unpolished’ <110> and <111> p-type Silicon Using Negative Potential Dissolution (NPD)

Experimental

The effect of NPD on surface topography of ‘as cut unpolished’ silicon wafers p-type (orientation <110> and <111>, 8-12 Ω-cm) was studied using a potassium hydroxide (KOH) etching solution, 24 wt. %, at 20° C. Experiments were conducted using an electrochemical apparatus (10 in FIG. 1, as described above) with an electrochemical flow-cell (12 in FIG. 1) containing a PEE™ (polyetheretherketone) holder equipped with an O-ring. The working area of the silicon electrode was 1 cm². In order to avoid stagnation and warming of the etching electrolyte, 4.5 liters of NaOH solution were used in each texturing experiment. The etching solution was circulated between the electrochemical cell (volume of 1.5 liters) and a reservoir vessel (volume of 3 liters) by a flow controllable peristaltic pump, at a pre-determined flow rate in the range of between 1 mL per minute and 250 mL per minute. An HP 6035A power supply was used in a constant potential mode. The negative (cathodic) potentials applied to the tested silicon electrodes were measured with the use of a Luggin capillary and a saturated calomel reference electrode (SCE), while a platinum wire was used as a counter electrode.

The silicon surface was treated by hydrofluoric (HF) acid in order to remove native oxide films, prior to immersion in the potassium (KOH) etching solution. Subsequent to the HF treatment, the silicon surface electrode was washed with distilled water. Cathodic polarization was applied after a short time, of about 5 min, of exposure in the KOH solution, allowing the potential of the silicon sample to reach a steady-state value, usually about −1.15 V. The textured silicon surface was examined using scanning electron microscopy (SEM, LEO-982 Geminate FEG-HRSEM).

Results and Discussion

FIG. 5 is an empirically determined graphical plot of cathodic current density (A/cm²) measured as a function of time (sec), of the as cut unpolished <100> p-type silicon, during exposure to a potassium hydroxide (KOH) etching solution, 24 wt %, at 20° C., negative biasing at negative (cathodic) potentials of −10 V, −20 V, −40 V, −45 V, and −50 V, relative to a standard calomel reference electrode (SCE), during dark conditions of non-specifically controlled and directed illumination by light, in particular, in the form of unprocessed surrounding or background ambient light having an intensity of less than 0.01 watts per cm² incident upon the negatively biased as cut unpolished silicon surface.

As shown in FIG. 5, the cathodic current density reached values of −0.019 and about −0.25 A/cm², at −10 V and −20 V, respectively, within a short time following initiation of the negative biasing. Further exposure to the cathodic bias did not practically change the value of cathodic current density. At a cathodic voltage of −40 V, the shape of the current-time curve markedly changed, becoming a type of ‘U’ shape: the value of cathodic current density soared to a maximum value immediately following initiation of the negative biasing, slowly decreased with time and reaching a minimum, followed by a gradual increase during further application of the negative biasing. The shift in the applied potential from −40 V to more negative values resulted in sufficient increase in the value of cathodic current density, and marked increase in the rate of the texturing stages. As seen in FIG. 5, the decrease in value of cathodic current density to the minimum and its second increase, occurred more rapidly once the applied potential was shifted to more highly negative values.

It was established that the ‘U’ shape current-time profile obtained with the as cut unpolished <110> p-type Si is characteristic for all the studied orientations of as cut unpolished p-type Si at potentials more negative than −20V. FIG. 6 is an empirically determined graphical plot of cathodic current density (A/cm²) measured as a function of time (sec), of the as cut unpolished <110> p-type silicon wafer, and the as cut unpolished <111> p-type silicon wafer, during separately exposing each to a potassium hydroxide (KOH) etching solution, 24 wt %, at 20° C., negative biasing at a negative (cathodic) potential of −40 V, and −45 V, respectively, relative to a standard calomel reference electrode (SCE), during dark conditions of non-specifically controlled and directed illumination by light, in particular, in the form of unprocessed surrounding or background ambient light having an intensity of less than 0.01 watts per cm² incident upon the negatively biased as cut unpolished silicon surface. As is seen, all the curves obtained with the as cut unpolished p-type Si electrodes with different orientation had the ‘U’ shape profile. The major differences between the profiles presented in FIG. 6 were the measured values of cathodic current density and the duration of the texturing.

FIGS. 7(a)-(c) are a series of HRSEM micrographs of exemplary embodiments of the surface of the as cut unpolished <110> p-type silicon wafer, and of the as cut unpolished <111> p-type silicon wafer: (a) pristine as cut unpolished <110> p-type silicon without subjection to wet etching and negative biasing; and, (b) textured as cut unpolished <111> p-type silicon and (c) textured as cut unpolished <110> p-type silicon, obtained at the minima values (indicated by the arrows in FIG. 6) of cathodic current density as a function of time, during the exemplary negative potential dissolution (NPD) procedure associated with FIG. 6. Micrographs were obtained from silicon samples polarized to the minima current values (0.5-0.7 A/cm²), as indicated by the arrows drawn in FIG. 6.

As shown in FIG. 7(c), the surface of the textured as cut unpolished <110> p-type silicon is covered with long prisms having length dimensions of 3-5 μm. As shown in FIG. 7(b), the surface of the textured as cut unpolished <111> p-type silicon is covered with coined triangles having side length of 7-10 μm. Thus, the use of negative potential dissolution (NPD) conditions, namely atypically low potentials along with suitable electrolyte solution, such as alkaline solution, allows rapid and selective texturing of the silicon samples. The actual type of textured surface produced depends upon the crystal orientation of the as cut unpolished silicon, while many other parameters apparently control and influence the negative potential dissolution (NPD) process. These other parameters are, for example, the other primary operating conditions and parameters of the negative potential dissolution (NPD) technique, being the type, concentration, and temperature, of the etching solution; and, the magnitude and duration of the negative biasing applied to the as cut unpolished silicon.

As was shown in FIG. 6, the current-time curve obtained from the as cut unpolished silicon samples has the ‘U’ shape. In order to understand this apparently unique current-time dependence, the topography developed on the <111> silicon surface was evaluated as a function of time, along the ‘U’ shape profile, as indicated in FIG. 6.

FIGS. 8(a)-(f) are a sequential time series of HRSEM micrographs of the surface of the as cut unpolished <111> p-type silicon wafer during the exemplary negative potential dissolution (NPD) procedure associated with FIG. 6, obtained at the same indicated times during the negative biasing (−45 V) time period: (a) 60 sec, (b) 300 sec, (c) 900 sec, (d) 1800 sec, (e) 2700 sec, and (f) 5100 sec. Within 60 seconds, no dramatic changes in the surface morphology are observed, although some minor modifications can be detected (in particular, when compared to the surface morphology of pristine as cut unpolished <110> p-type silicon (which is very similar to that of pristine as cut unpolished <111> p-type silicon) shown in FIG. 7(a). After 300 seconds, many triangle features textured in the silicon substrate are visible. The side length of these triangles is less than 5 m. Within 900 seconds, the whole surface is textured with triangles, having dimensions of about 10 μm. Enlargement of textured triangles and a complete surface texturing with sides length of about 20 μm are detected within 1800 seconds. Within 1800 seconds, the first signs of over-texturing and holes drilled into the surface are seen, while diminishing of surface texturing starts to be visible. This process continues, and after 2700 seconds, the formations of holes drilled into the surface are seen. After 5100 seconds, the surface is packed with combined holes, while the intact surface area is smoother.

FIG. 9 is a graphical plot of cathodic current density (A/cm²) as a function of time (sec), representing an exemplary proposed model graphically illustrating the multi-phenomenological behavior, including the ‘U’ shape profile, of the value of cathodic current density of an as cut unpolished semiconductor material as a function of time, during the negative biasing time period, during dark conditions. The initial increase in the value of cathodic current density observed in the first seconds is most probably due to the existence of numerous surface defects and/or defect zones in the as cut unpolished silicon samples. The following decrease in the value of cathodic current density is due to two parallel surface processes simultaneously taking place: (i) removal of surface defects and/or defect zones, and (ii) initial surface texturing. The extensive plateau at almost constant low values of cathodic current density reflects texturing of the silicon surface, while the rapid increase in the value of cathodic current density is most likely due to surface area increase caused by an extensively over-textured surface.

Clearly, the rate and extent of texturing of the silicon surfaces, and therefore, the type of textured silicon surfaces formed therefrom, are controllable and significantly influenced by the several primary operating conditions and parameters of the negative potential dissolution (NPD) technique, such as type of the semiconductor material; type, concentration, temperature, and flow rate, of the etching solution; and, magnitude and duration of the negative biasing.

Thus, the present invention, as illustratively described and exemplified hereinabove, is generally applicable to a wide variety of different types of semiconductor materials, including, for example, different types of polished semiconductor materials, and different types of ‘as cut unpolished’ semiconductor materials. The present invention is generally applicable to a variety of different fields and sub-fields requiring or involving texturing the surface of semiconductor materials and textured semiconductor materials formed therefrom, and is particularly applicable to the field of manufacturing solar cells or photovoltaic panels from semiconductor materials, involving texturing surfaces of the semiconductor materials for the objective of decreasing reflectance of incident sunlight away from the semiconductor material surfaces, thereby improving trapping of the solar energy inside the semiconductor materials of the solar cells or photovoltaic panels. Moreover, the present invention is applicable as (i) a specifically designated, stand-alone, method for texturing a semiconductor material, or (ii) as part of a more encompassing multi-stage method for processing or manufacturing a semiconductor material, or (iii) as part of a more encompassing multi-stage method for processing or manufacturing a product, for example, a solar cell or photovoltaic panel, made from a semiconductor material.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

While the invention has been described in conjunction with specific embodiments and examples thereof, it is evident that many alternatives, modifications and variations will be apparent to those skilled in the art. Accordingly, it is intended to embrace all such alternatives, modifications and variations that fall within the spirit and broad scope of the appended claims.

1. A method for texturing a semiconductor material, comprising the steps of:
(a) exposing at least part of a surface of the semiconductor material to an etching solution, such that said exposed part of said surface is contacted and wetted by said etching solution;
(b) negatively biasing the semiconductor material to a potential more negative than minus sixty volts relative to a standard reference electrode; and
(c) illuminating said exposed part of said surface contacted and wetted by said etching solution, during said negative biasing, for a period of time starting from initiation of said illuminating, such that value of cathodic current density of the semiconductor material is significantly higher at end of said illumination time period than at beginning of said illumination time period.

2. The method of claim 1, wherein the semiconductor material is selected from the group consisting of silicon (Si), germanium (Ge), and a combination thereof.

3. The method of claim 1, wherein the semiconductor material is an alloy selected from the group consisting of a silicon-germanium alloy, a silicon-carbon alloy, a germanium-carbon alloy, a silicon-nitrogen alloy, and a combination thereof.

4. The method of claim 1, wherein the semiconductor material is selected from the group consisting of a metal oxide, a metal phosphide, a metal sulfide, a metal arsenide, a metal selenide, a metal telluride, and a combination thereof.

5. The method of claim 1, wherein the semiconductor material includes a non-semiconductor material.

6. The method of claim 1, wherein doped conductive type of the semiconductor material is variable.

7. The method of claim 1, wherein the semiconductor material is a doped conductive type of silicon selected from the group consisting of a doped p-type silicon, a doped n-type silicon, and a combination thereof.

8. The method of claim 1, wherein grade of the semiconductor material is selected from the group consisting of a metallurgical grade and a semiconductor grade.

9. The method of claim 1, wherein geometrical configuration, shape, or form, of the semiconductor material is selected from the group consisting of amorphous, mono-crystalline, poly-crystalline, multi-crystalline, and a combination thereof.

10. The method of claim 9, wherein type of crystallinity or crystallographic orientation is variable for a said mono-crystalline, a said poly-crystalline, a said multi-crystalline, or a said combination thereof, type of said geometrical configuration, shape, or form, of the semiconductor material.

11. The method of claim 1, wherein the semiconductor material is silicon having a type of crystallinity or crystallographic orientation selected from the group consisting of <100>, <1 10>, and <111>.

12. The method of claim 1, wherein dimensions of the semiconductor material are selected from the group consisting of on order of sub-microns, on order of microns, on order of millimeters, on order of centimeters, on order of at least a meter, and a combination thereof.

13. The method of claim 1, wherein construction of the semiconductor material is selected from the group consisting of part of a single assembly, a composite of two or more parts of a single assembly, a single complete assembly, a composite of two or more single complete assemblies, and a combination thereof.

14. The method of claim 1, wherein construction of the semiconductor material is selected from the group consisting of part of a single wafer, a composite of two or more parts of a single wafer, a single complete wafer, a composite of two or more single complete wafers, and a combination thereof.

15. The method of claim 1, wherein construction of the semiconductor material is selected from the group consisting of a thin film, a thick film, and a combination thereof.

16. The method of claim 1, wherein construction of the semiconductor material includes a substrate.

17. The method of claim 1, wherein the semiconductor material is in a non-masked form.

18. The method of claim 1, wherein the semiconductor material is in a masked form.

19. The method of claim 1, wherein the semiconductor material is in a polished form.

20. The method of claim 1, wherein the semiconductor material is in an as cut unpolished form.

21. The method of claim 1, wherein the semiconductor material is used for manufacturing a solar cell or a photovoltaic panel.

22. The method of claim 1, wherein type of said etching solution is selected from the group consisting of an acidic etching solution, a neutral etching solution, a basic or alkaline etching solution, and a molten etching solution.

23. The method of claim 22, wherein said acidic etching solution is an acidic aqueous solution selected from the group consisting of hydrofluoric acid (HF), nitric acid (HNO₃), phosphoric acid (H₃PO₄), and a combination thereof.

24. The method of claim 22, wherein said neutral etching solution is selected from the group consisting of a neutral aqueous solution including dissolved ions, and, an organic solution.

25. The method of claim 22, wherein said basic or alkaline etching solution is a basic or alkaline aqueous solution of an alkali hydroxide.

26. The method of claim 22, wherein said molten etching solution is a solution of a melted salt.

27. The method of claim 1, wherein concentration of solute in said etching solution is at least about 0.001 M.

28. The method of claim 1, wherein concentration of solute in said etching solution is in a range of between about 8% (wt. solute/wt. solution) and about 50% (wt. solute/wt. solution).

29. The method of claim 1, wherein temperature of said etching solution is in a range of between about freezing point of said etching solution and about boiling point of said etching solution.

30. The method of claim 1, wherein said etching solution is aqueous, and temperature of said aqueous etching solution is in a range of between about 20° C. and about 90° C.

31. The method of claim 1, wherein said etching solution is aqueous, and temperature of said aqueous etching solution is in a range of between about 50° C. and about 90° C.

32. The method of claim 1, wherein flow rate of said etching solution contacting and wetting said surface of the semiconductor material is in a range of between about 0 liter per minute and about 10 liters per minute.

33. The method of claim 1, wherein flow rate of said etching solution contacting and wetting said surface of the semiconductor material is in a range of between about 1 mL per minute and about 2.5 liters per minute.

34. The method of claim 1, wherein flow rate of said etching solution contacting and wetting said surface of the semiconductor material is in a range of between about 1 mL per minute and about 250 mL per minute.

35. The method of claim 1, wherein step (a) is performed for a period of time of at least about one minute prior to initiating step (b) of said negative biasing of the semiconductor material, such that said exposed part of said surface reaches a steady-state value of an open circuit potential (OCP) relative to said standard reference electrode.

36. The method of claim 1, wherein step (b), the semiconductor material is negatively biased to a said potential in a range of between more negative than minus sixty volts and about minus one hundred volts relative to said standard reference electrode.

37. The method of claim 1, wherein step (b), the semiconductor material is negatively biased to a said potential more negative than minus one hundred volts relative to said standard reference electrode.

38. The method of claim 1, wherein said negative biasing of step (b) is performed for a period of time of at least about one minute, prior to initiating said illuminating of step (c), such that the semiconductor material reaches a steady-state value of said applied negative potential relative to said standard reference electrode, and such that there is establishing a steady-state value of said cathodic current density of the semiconductor material.

39. The method of claim 1, wherein step (c), said illuminating is performed by a specifically controlled and directed light source which generates specifically controlled and directed-generated light in a form of non-ambient light.

40. The method of claim 39, wherein said specifically controlled and directed light source is selected from the group consisting of a halogen lamp, a tungsten-halogen lamp, and a dye laser.

41. The method of claim 39, wherein a specifically controlled and directed-processed light, in a form of processed said non-ambient light, is formed from intentional processing of said specifically controlled and directed-generated light, and is directed toward said exposed part of said surface of the semiconductor material.

42. The method of claim 41, wherein said specifically controlled and directed-generated light, together with said specifically controlled and directed-processed light, are specifically controlled and directed for producing said processed non-ambient light having an intensity of at least 0.01 watts per cm² at said negatively biased semiconductor material surface that is contacted and wetted by said etching solution.

43. The method of claim 41, wherein said specifically controlled and directed-generated light, together with said specifically controlled and directed-processed light, are specifically controlled and directed for producing said processed non-ambient light having an intensity in a range of between about 0.5 watts per cm² and about 5.0 watts per cm² at said negatively biased semiconductor material surface that is contacted and wetted by said etching solution.

44. The method of claim 41, wherein said specifically controlled and directed-processed light, incident upon said negatively biased semiconductor material surface that is contacted and wetted by etching solution, is light selected from the group consisting of polychromatic light, monochromatic light, poly- or multi-monochromatic light, and combinations thereof.

45. The method of claim 41, wherein said specifically controlled and directed-processed light, incident upon said negatively biased semiconductor material surface that is contacted and wetted by etching solution, has a wavelength in a range of between about 100 nm and about 0.5 mm.

46. The method of claim 41, wherein said specifically controlled and directed-processed light, incident upon said negatively biased semiconductor material surface that is contacted and wetted by etching solution, has a wavelength in a range of between about 250 nm and about 1500 nm.

47. The method of claim 41, wherein said specifically controlled and directed-processed light, incident upon said negatively biased semiconductor material surface that is contacted and wetted by etching solution, has a wavelength in a range of between about 280 nm and about 500 nm.

48. The method of claim 1, wherein step (c), within about one second of initiating said illumination of said exposed part of said surface during said negative biasing, said value of said cathodic current density of the semiconductor material instantaneously increases to a value corresponding to that at said beginning of said illumination time period.

49. The method of claim 48, wherein during remainder of duration of said illumination time period, actual form and magnitude of said increase in said value of said cathodic current density of the semiconductor material from said value at said beginning of said illumination time period to said value at said end of said illumination time period, are functions of a combination of operating conditions and parameters being type of the semiconductor material; type, concentration, temperature, and flow rate, of said etching solution; magnitude and duration of said negative biasing; and intensity, wavelength, and duration, of said illumination incident upon said negatively biased semiconductor material surface.

50. The method of claim 1, wherein step (c), said period of time is about 60 seconds, starting from initiation of said illuminating.

51. The method of claim 1, wherein step (c), said period of time is about 600 seconds, starting from initiation of said illuminating.

52. The method of claim 1, wherein step (c), said period of time is about 5000 seconds, starting from initiation of said illuminating.

53. A method for texturing an as cut unpolished semiconductor material, comprising the steps of:
(a) exposing at least part of a surface of the as cut unpolished semiconductor material to an etching solution, such that said exposed part of said surface is contacted and wetted by said etching solution; and
(b) negatively biasing the as cut unpolished semiconductor material to a negative potential of at least minus one volt relative to a standard reference electrode for a period of time, during which the as cut unpolished semiconductor material is illuminated by light having an intensity of less than 0.01 watts per cm², such that value of cathodic current density of the as cut unpolished semiconductor material as a function of time during said time period initially increases to a maximum value, then decreases to a series of values each being significantly less than said maximum value.

54. The method of claim 53, wherein the as cut unpolished semiconductor material is selected from the group consisting of silicon (Si), germanium (Ge), and a combination thereof.

55. The method of claim 53, wherein the as cut unpolished semiconductor material is an alloy selected from the group consisting of a silicon-germanium alloy, a silicon-carbon alloy, a germanium-carbon alloy, a silicon-nitrogen alloy, and a combination thereof.

56. The method of claim 53, wherein the as cut unpolished semiconductor material is selected from the group consisting of a metal oxide, a metal phosphide, a metal sulfide, a metal arsenide, a metal selenide, a metal telluride, and a combination thereof.

57. The method of claim 53, wherein the as cut unpolished semiconductor material includes a non-semiconductor material.

58. The method of claim 53, wherein doped conductive type of the as cut unpolished semiconductor material is variable.

59. The method of claim 53, wherein the as cut unpolished semiconductor material is a doped conductive type of silicon selected from the group consisting of a doped p-type silicon, a doped n-type silicon, and a combination thereof.

60. The method of claim 53, wherein grade of the as cut unpolished semiconductor material is selected from the group consisting of a metallurgical grade and a semiconductor grade.

61. The method of claim 53, wherein geometrical configuration, shape, or form, of the as cut unpolished semiconductor material is selected from the group consisting of amorphous, mono-crystalline, poly-crystalline, multi-crystalline, and a combination thereof.

62. The method of claim 61, wherein type of crystallinity or crystallographic orientation is variable for a said mono-crystalline, a said poly-crystalline, a said multi-crystalline, or a said combination thereof, type of said geometrical configuration, shape, or form, of the as cut unpolished semiconductor material.

63. The method of claim 53, wherein the as cut unpolished semiconductor material is silicon having a type of crystallinity or crystallographic orientation selected from the group consisting of <100>, <110>, and <111>.

64. The method of claim 53, wherein dimensions of the as cut unpolished semiconductor material are selected from the group consisting of on order of sub-microns, on order of microns, on order of millimeters, on order of centimeters, on order of at least a meter, and a combination thereof.

65. The method of claim 53, wherein construction of the as cut unpolished semiconductor material is selected from the group consisting of part of a single assembly, a composite of two or more parts of a single assembly, a single complete assembly, a composite of two or more single complete assemblies, and a combination thereof.

66. The method of claim 53, wherein construction of the as cut unpolished semiconductor material is selected from the group consisting of part of a single wafer, a composite of two or more parts of a single wafer, a single complete wafer, a composite of two or more single complete wafers, and a combination thereof.

67. The method of claim 53, wherein construction of the as cut unpolished semiconductor material is selected from the group consisting of a thin film, a thick film, and a combination thereof.

68. The method of claim 53, wherein construction of the as cut unpolished semiconductor material includes a substrate.

69. The method of claim 53, wherein the as cut unpolished semiconductor material is in a non-masked form.

70. The method of claim 53, wherein the as cut unpolished semiconductor material is in a masked form.

71. The method of claim 53, wherein the as cut unpolished semiconductor material is used for manufacturing a solar cell or a photovoltaic panel.

72. The method of claim 53, wherein type of said etching solution is selected from the group consisting of an acidic etching solution, a neutral etching solution, a basic or alkaline etching solution, and a molten etching solution.

73. The method of claim 72, wherein said acidic etching solution is an acidic aqueous solution selected from the group consisting of hydrofluoric acid (HF), nitric acid (HNO₃), phosphoric acid (H₃PO₄), and a combination thereof.

74. The method of claim 72, wherein said neutral etching solution is selected from the group consisting of a neutral aqueous solution including dissolved ions, and, an organic solution.

75. The method of claim 72, wherein said basic or alkaline etching solution is a basic or alkaline aqueous solution of an alkali hydroxide.

76. The method of claim 72, wherein said molten etching solution is a solution of a melted salt.

77. The method of claim 53, wherein concentration of solute in said etching solution is at least about 0.001 M.

78. The method of claim 53, wherein concentration of solute in said etching solution is in a range of between about 8% (wt. solute/wt. solution) and about 50% (wt. solute/wt. solution).

79. The method of claim 53, wherein temperature of said etching solution is in a range of between about freezing point of said etching solution and about boiling point of said etching solution.

80. The method of claim 53, wherein said etching solution is aqueous, and temperature of said aqueous etching solution is in a range of between about 20° C. and about 90° C.

81. The method of claim 53, wherein said etching solution is aqueous, and temperature of said aqueous etching solution is in a range of between about 50° C. and about 90° C.

82. The method of claim 53, wherein flow rate of said etching solution contacting and wetting said surface of the as cut unpolished semiconductor material is in a range of between about 0 liter per minute and about 10 liters per minute.

83. The method of claim 53, wherein flow rate of said etching solution contacting and wetting said surface of the as cut unpolished semiconductor material is in a range of between about 1 mL per minute and about 2.5 liters per minute.

84. The method of claim 53, wherein flow rate of said etching solution contacting and wetting said surface of the as cut unpolished semiconductor material is in a range of between about 1 mL per minute and about 250 mL per minute.

85. The method of claim 53, wherein step (a) is performed for a period of time of at least about one minute prior to initiating step (b) of said negative biasing of the as cut unpolished semiconductor material, such that said exposed part of said surface reaches a steady-state value of an open circuit potential (OCP) relative to said standard reference electrode.

86. The method of claim 53, wherein step (b), the as cut unpolished semiconductor material is negatively biased to a said negative potential in a range of between said at least minus one volt and about minus one hundred volts relative to said standard reference electrode.

87. The method of claim 53, wherein step (b), the as cut unpolished semiconductor material is negatively biased to a said negative potential in a range of between at least minus ten volts and about minus one hundred volts relative to said standard reference electrode.

88. The method of claim 53, wherein step (b), the as cut unpolished semiconductor material is negatively biased to a said negative potential in a range of between at least minus twenty volts and about minus fifty volts relative to said standard reference electrode.

89. The method of claim 53, wherein during said negative biasing time period, actual form and magnitude of said initial increase in said value of said cathodic current density of the as cut unpolished semiconductor material to said maximum value, then decrease in said value of said cathodic current density of the as cut unpolished semiconductor material to said series of said values each being significantly less than said maximum value, are functions of a combination of operating conditions and parameters of type of the semiconductor material; type, concentration, temperature, and flow rate, of said etching solution; and, magnitude and duration of said negative biasing.

90. The method of claim 53, wherein step (b), said period of time is in a range of between about 120 seconds and about 2100 seconds, starting from initiating of said negative biasing of the as cut unpolished semiconductor material.

91. The method of claim 53, wherein step (b) said illuminating is performed by a non-specifically controlled and directed light source which generates non-specifically controlled and directed-generated (unprocessed) light in a form of ambient light.

92. A method for texturing an as cut unpolished semiconductor material, consisting essentially of the steps of:
(a) exposing at least part of a surface of the as cut unpolished semiconductor material to an etching solution, such that said exposed part of said surface is contacted and wetted by said etching solution; and
(b) negatively biasing the as cut unpolished semiconductor material to a negative potential of at least minus one volt relative to a standard reference electrode for a period of time, such that value of cathodic current density of the as cut unpolished semiconductor material as a function of time during said time period initially increases to a maximum value, then decreases to a series of values each being significantly less than said maximum value.

93. A textured semiconductor material, textured by the method comprising the steps of:
(a) providing a semiconductor material;
(b) exposing at least part of a surface of said semiconductor material to an etching solution, such that said exposed part of said surface is contacted and wetted by said etching solution;
(c) negatively biasing said semiconductor material to a potential more negative than minus sixty volts relative to a standard reference electrode; and
(d) illuminating said exposed part of said surface contacted and wetted by said etching solution, during said negative biasing, for a period of time starting from initiation of said illuminating, such that value of cathodic current density of said semiconductor material is significantly higher at end of said illumination time period than at beginning of said illumination time period.

94. The textured semiconductor material of claim 93, wherein morphology of at least part of said surface of the textured semiconductor material is characterized by presence of pyramids.

95. The textured semiconductor material of claim 93, wherein morphology of at least part of said surface of the textured semiconductor material is characterized by presence of inverted pyramids.

96. A textured as cut unpolished semiconductor material, textured by the method comprising the steps of:
(a) providing an as cut unpolished semiconductor material;
(b) exposing at least part of a surface of said as cut unpolished semiconductor material to an etching solution, such that said exposed part of said surface is contacted and wetted by said etching solution; and
(c) negatively biasing said as cut unpolished semiconductor material to a negative potential of at least minus one volt relative to a standard reference electrode for a period of time, during which said as cut unpolished semiconductor material is illuminated by light having an intensity of less than 0.01 watts per cm², such that value of cathodic current density of said as cut unpolished semiconductor material as a function of time during said time period initially increases to a maximum value, then decreases to a series of values each being significantly less than said maximum value.

97. The textured as cut unpolished semiconductor material of claim 96, wherein morphology of at least part of said surface of the textured as cut unpolished semiconductor material is characterized by presence of long prisms or coined triangles.

98. The textured as cut unpolished semiconductor material of claim 96, wherein morphology of at least part of said surface of the textured as cut unpolished semiconductor material is a function of crystal orientation of the as cut unpolished semiconductor material.

99. A textured as cut unpolished semiconductor material, textured by the method consisting essentially of the steps of:
(a) providing an as cut unpolished semiconductor material;
(b) exposing at least part of a surface of said as cut unpolished semiconductor material to an etching solution, such that said exposed part of said surface is contacted and wetted by said etching solution; and
(c) negatively biasing said as cut unpolished semiconductor material to a negative potential of at least minus one volt relative to a standard reference electrode for a period of time, such that value of cathodic current density of said as cut unpolished semiconductor material as a function of time during said time period initially increases to a maximum value, then decreases to a series of values each being significantly less than said maximum value.

100. The textured as cut unpolished semiconductor material of claim 99, wherein morphology of at least part of said surface of the textured as cut unpolished semiconductor material is characterized by presence of long prisms or coined triangles.

101. The textured as cut unpolished semiconductor material of claim 99 wherein morphology of at least part of said surface of the textured as cut unpolished semiconductor material is a function of crystal orientation of the as cut unpolished semiconductor material.
